(19) United States
(12) Patent Application Publication
(10) Pub. No.: US 2025/0210249 A1
(43) Pub. Date: Jun. 26, 2025

(54) INDUCTOR ARRAY

(71) Applicant: TAIYO YUDEN CO., LTD., Tokyo (JP)

(72) Inventors: Takayuki ARAI, Tokyo (JP); Naoya TERAUCHI, Tokyo (JP); Tomoo KASHIWA, Tokyo (JP)

(21) Appl. No.: 19/073,792

(22) Filed: Mar. 7, 2025

Related U.S. Application Data
(63) Continuation of application No. 17/388,065, filed on Jul. 29, 2021.

(30) Foreign Application Priority Data
Jul. 31, 2020 (JP) 2020-130032
Jul. 31, 2020 (JP) 2020-130043

(51) Int. Cl. H01F 27/29; H01F 27/24; H01F 27/28

(52) U.S. Cl. CPC H01F 27/292; H01F 27/24; H01F 27/2804; H01F 2027/2809

(57) ABSTRACT

An inductor array includes a base body having a first surface, first to fourth external electrodes touching the first surface, a first internal conductor provided in the base body and connected at the ends thereof to the first and second external electrodes, and a second internal conductor provided in the base body and connected at the ends thereof to the third and fourth external electrodes. The first and second internal conductors are spaced away from each other in a reference direction. The first internal conductor has a first aspect ratio of greater than one, where the first aspect ratio denotes a ratio of (i) a dimension of a section of the first internal conductor orthogonal to a current flowing direction in a direction perpendicular to the reference direction to (ii) a dimension of the section in the reference direction.

### CROSS-REFERENCE TO RELATED APPLICATIONS

This application is a continuation of U.S. patent application Ser. No. 17/388,065 (filed on Jul. 29, 2021), which claims the benefit of priority from Japanese Patent Applications Serial Nos. 2020-130032 and 2020-130043 (filed on Jul. 31, 2020), the contents of which are hereby incorporated by reference in their entirety.

### TECHNICAL FIELD

The present disclosure relates to an inductor array, a circuit board including the inductor array, and an electronic device including the circuit board.

### BACKGROUND

An inductor array including a plurality of inductors has been known. A plurality of inductors are packaged in a single chip to form such an inductor array. A typical conventional inductor array includes a base body, a plurality of internal conductors provided in the base body and insulated from each other in the base body, and a plurality of external electrodes connected to the plurality of internal conductors at respective ends thereof. Examples of the conventional inductor array are disclosed, for example, in Japanese Patent Application Publication No. 2016-006830 (the '830 Publication) and Japanese Patent Application Publication No. 2019-153649 (the '649 Publication).

The inductor array disclosed in '830 Publication includes internal conductors, which are each wound around a coil axis extending perpendicularly to the mounting surface. Generally, the internal conductors included in the inductor array have a larger size in the direction perpendicular to the coil axis than in the direction parallel to the coil axis. The inductor array disclosed in '830 Publication thus disadvantageously has a large size in the direction extending along the mounting surface of the base body as the number of the inductors increases. In other words, the inductor array disclosed in '830 Publication encounters difficulties in making attempts to reduce the size in the direction extending along the mounting surface.

The '649 Publication discloses an inductor array including a plurality of internal conductors, and each internal conductor has its ends externally exposed through the mounting surface. To achieve size reduction for the inductor array disclosed in '649 Publication, the inductors included in the inductor array may be arranged closer to each other. This, however, may increase the magnetic coupling between the inductors and make it difficult for the respective inductors to exhibit their own characteristics.

### SUMMARY

An object of the present invention is to solve or relieve at least a part of the above problem. One particular object of the present invention is to provide an inductor array having lessened magnetic coupling between the inductors. One particular object of the present invention is to provide an inductor array that can achieve a smaller size in the direction extending along the mounting surface and that has lessened magnetic coupling between the inductors.

Other objects of the present invention will be made apparent through the entire description in the specification. The invention disclosed herein may address other drawbacks in addition to the drawback described above.

An inductor array according to one or more embodiments of the present invention includes a base body containing a plurality of metal magnetic particles, where the base body has a first surface, a first external electrode provided on the base body such that the first external electrode at least touches the first surface, a second external electrode provided on the base body such that the second external electrode at least touches the first surface, a third external electrode provided on the base body such that the third external electrode at least touches the first surface, a fourth external electrode provided on the base body such that the fourth external electrode at least touches the first surface, a first internal conductor provided in the base body such that the first internal conductor is connected at one of ends thereof to the first external electrode and at the other of the ends thereof to the second external electrode, and a second internal conductor provided in the base body such that the second internal conductor is connected at one of ends thereof to the third external electrode and at the other of the ends thereof to the fourth external electrode. In one or more embodiments of the present invention, the second internal conductor is spaced away from the first internal conductor in a reference direction. In one or more embodiments of the present invention, a section of the first internal conductor orthogonal to a current flowing direction has a first aspect ratio of greater than one, where the first aspect ratio denotes a ratio of (i) a dimension of the section in a direction perpendicular to the reference direction to (ii) a dimension of the section in the reference direction. In one or more embodiments of the present invention, a section of the second internal conductor orthogonal to a current flowing direction has a second aspect ratio of greater than one, where the second aspect ratio denotes a ratio of (i) a dimension of the section in a direction perpendicular to the reference direction to (ii) a dimension of the section in the reference direction.

In one or more embodiments of the present invention, a spacing between the first internal conductor and the second internal conductor in the reference direction is 0.3 mm or less.

In one or more embodiments of the present invention, the base body has a relative magnetic permeability of 100 or less.

In one or more embodiments of the present invention, the first internal conductor extends linearly from the first external electrode to the second external electrode when seen in a direction perpendicular to the first surface of the base body, and the second internal conductor extends linearly from the third external electrode to the fourth external electrode when seen in the direction perpendicular to the first surface of the base body.

In one or more embodiments of the present invention, when seen in the reference direction, a shape of the first internal conductor is the same as a shape of the second internal conductor.

In one or more embodiments of the present invention, an absolute value of a coefficient of coupling between the first and second internal conductors is 0.15 or less.

In one or more embodiments of the present invention, the first internal conductor has a rounded section when cut along a plane perpendicular to the current flowing direction.

In one or more embodiments of the present invention, the inductor array includes a fifth external electrode provided on the base body such that the fifth external electrode at least touches the first surface, a sixth external electrode provided on the base body such that the sixth external electrode at least touches the first surface, and a third internal conductor provided in the base body such that the third internal conductor is connected at one of ends thereof to the fifth external electrode and at the other of the ends thereof to the sixth external electrode. In one or more embodiments of the present invention, the third internal conductor is spaced away from the second internal conductor and positioned opposite the first internal conductor with respect to the second internal conductor in the reference direction. In one or more embodiments of the present invention, a section of the third internal conductor orthogonal to a current flowing direction has a third aspect ratio of greater than one, where the third aspect ratio denotes a ratio of (i) a dimension of the section in a direction perpendicular to the reference direction to (ii) a dimension of the section in the reference direction.

In one or more embodiments of the present invention, when seen in the reference direction, a shape of the third internal conductor is the same as at least one of a shape of the first internal conductor or a shape of the second internal conductor.

In one or more embodiments of the present invention, the base body has a first end surface connected to the first surface, the first internal conductor is arranged such that the first internal conductor faces the first end surface of the base body in the reference direction, and a spacing between the second internal conductor and the third internal conductor in the reference direction is greater than a spacing between the first internal conductor and the second internal conductor in the reference direction.

In one or more embodiments of the present invention, the inductor array includes a seventh external electrode provided on the base body such that the seventh external electrode at least touches the first surface, an eighth external electrode provided on the base body such that the eighth external electrode at least touches the first surface, and a fourth internal conductor provided in the base body such that the fourth internal conductor is connected at one of ends thereof to the seventh external electrode and at the other of the ends thereof to the eighth external electrode. In one or more embodiments of the present invention, the fourth internal conductor is spaced away from the third internal conductor and positioned opposite the second internal conductor with respect to the third internal conductor in the reference direction. In one or more embodiments of the present invention, a section of the fourth internal conductor orthogonal to a current flowing direction has a fourth aspect ratio of greater than one, where the fourth aspect ratio denotes a ratio of (i) a dimension of the section in a direction perpendicular to the reference direction to (ii) a dimension of the section in the reference direction.

In one or more embodiments of the present invention, when seen in the reference direction, a shape of the fourth internal conductor is the same as at least one of a shape of the first internal conductor, a shape of the second internal conductor or a shape of the third internal conductor.

In one or more embodiments of the present invention, the base body has a second end surface connected to the first surface and opposed to the first end surface, and the fourth internal conductor is arranged such that the fourth internal conductor faces the second end surface of the base body in the reference direction. In one or more embodiments of the present invention, a spacing between the second internal conductor and the third internal conductor in the reference direction is greater than a spacing between the third internal conductor and the fourth internal conductor in the reference direction.

In one or more embodiments of the present invention, the base body has a first side surface connected to the first surface and a second side surface opposed to the first side surface. In one or more embodiments of the present invention, one of ends of the first internal conductor is exposed through the first side surface to outside of the base body and connected to the first external electrode, and the other of the ends of the first internal conductor is exposed through the second side surface to outside of the base body and connected to the second external electrode. In one or more embodiments of the present invention, one of ends of the second internal conductor is exposed through the first side surface to outside of the base body and connected to the third external electrode, and the other of the ends of the second internal conductor is exposed through the second side surface to outside of the base body and connected to the fourth external electrode.

An inductor array according to one or more embodiments of the present invention includes a base body containing a plurality of metal magnetic particles, where the base body has a first surface, a first internal conductor provided in the base body, where the first internal conductor includes a first winding portion wound around a first coil axis positioned away from the first surface by a first distance and extending in a direction parallel to the first surface, a second internal conductor provided in the base body, where the second internal conductor including a second winding portion wound around a second coil axis positioned away from the first surface by a second distance greater than the first distance and extending in a direction parallel to the first coil axis, a first external electrode provided on the base body such that the first external electrode at least touches the first surface, where the first external electrode is connected to one of ends of the first internal conductor, a second external electrode provided on the base body such that the second external electrode at least touches the first surface, where the second external electrode is connected to the other of the ends of the first internal conductor, a third external electrode provided on the base body such that the third external electrode at least touches the first surface, where the third external electrode is connected to one of ends of the second internal conductor, and a fourth external electrode provided on the base body such that the fourth external electrode at least touches the first surface, where the fourth external electrode is connected to the other of the ends of the second internal conductor.

In one or more embodiments of the invention, a spacing between the first internal conductor and the second internal conductor in a direction extending along the first coil axis is 0.3 mm or less.

In one or more embodiments of the present invention, the base body has a relative magnetic permeability of 100 or less.

In one or more embodiments of the present invention, the first winding portion is wound around the first coil axis 1.5 turns or less, and the second winding portion is wound around the second coil axis 1.5 turns or less.

In one or more embodiments of the present invention, a shape of the first winding portion when seen in a direction of the first coil axis is the same as a shape of the second winding portion when seen in a direction of the second coil axis.

In one or more embodiments of the invention, an absolute value of a coefficient of coupling between the first and second internal conductors is 0.15 or less.

In one or more embodiments of the present invention, a section of the first winding portion has a first aspect ratio of greater than one, where the first aspect ratio denotes a ratio of (i) a dimension of the section in a direction perpendicular to the first coil axis to (ii) a dimension of the section in a direction parallel to the first coil axis.

In one or more embodiments of the present invention, a section of the second winding portion has a second aspect ratio of greater than one, where the second aspect ratio denotes a ratio of (i) a dimension of the section in a direction perpendicular to the second coil axis to (ii) a dimension of the section in a direction parallel to the second coil axis.

In one or more embodiments of the present invention, the first winding portion has a first winding pattern extending around the first coil axis, and the first winding pattern has a rounded section when cut along a plane passing through the first coil axis.

In one or more embodiments of the present invention, the base body has a first end surface connected to the first surface, the first internal conductor has a first lead-out conductor connected to one of ends of the first winding portion and extending along the first end surface, and the first external electrode is connected to the first internal conductor via the first lead-out conductor.

An inductor array according to one or more embodiments of the present invention includes a third internal conductor provided in the base body such that the third internal conductor is positioned opposite the first internal conductor with respect to the second internal conductor, where the third internal conductor has a third winding portion wound around a third coil axis, and the third coil axis is positioned away from the first surface by a third distance less than the second distance and extends in a direction parallel to the first coil axis, a fifth external electrode connected to one of ends of the third internal conductor and a sixth external electrode connected to the other of the ends of the third internal conductor.

In one or more embodiments of the present invention, the third distance is equal to the first distance.

In one or more embodiments of the present invention, a shape of the third winding portion when seen in a direction of the third coil axis is the same as at least one of a shape of the first winding portion when seen in a direction of the first coil axis or a shape of the second winding portion when seen in a direction of the second coil axis.

In one or more embodiments of the present invention, the base body has a first end surface connected to the first surface, the first internal conductor is arranged such that the first internal conductor faces the first end surface of the base body in the direction extending along the first coil axis, and a spacing between the second internal conductor and the third internal conductor in a direction extending along the first coil axis is greater than a spacing between the first internal conductor and the second internal conductor in a direction extending along the first coil axis.

An inductor array according to one or more embodiments of the present invention includes a fourth internal conductor provided in the base body such that the fourth internal conductor is positioned opposite the second internal conductor with respect to the third internal conductor, where the fourth internal conductor has a fourth winding portion wound around a fourth coil axis, and the fourth coil axis is positioned away from the first surface by a fourth distance greater than the third distance and extending in a direction parallel to the first coil axis, a seventh external electrode connected to one of ends of the fourth internal conductor, and an eighth external electrode connected to the other of the ends of the fourth internal conductor.

In one or more embodiments of the present invention, the fourth distance is equal to the second distance.

In one or more embodiments of the present invention, a shape of the fourth winding portion when seen in a direction of the fourth coil axis is the same as at least one of a shape of the first winding portion when seen in a direction of the first coil axis, a shape of the second winding portion when seen in a direction of the second coil axis, or a shape of the third winding portion when seen in a direction of the third coil axis.

In one or more embodiments of the present invention, the base body has a second end surface connected to the first surface and facing the first end surface, the fourth internal conductor is arranged such that the fourth internal conductor faces the second end surface of the base body in a direction extending along the first coil axis, and a spacing between the second and third internal conductors in a direction extending along the third coil axis is greater than a spacing between the third and fourth internal conductors in a direction extending along the third coil axis.

An embodiment of the present invention relates to a circuit board including any one of the above-described inductor arrays.

An embodiment of the present invention relates to an electronic device including the above circuit board.

### ADVANTAGEOUS EFFECTS

The techniques disclosed herein can provide an inductor array having lessened magnetic coupling between the inductors. The techniques disclosed herein can provide an inductor array that can achieve a smaller size in the direction extending along the mounting surface and that has lessened magnetic coupling between the inductors.

### BRIEF DESCRIPTION OF THE DRAWINGS

FIG. 1 is a perspective view of an inductor array according to one embodiment of the invention mounted on a mounting substrate.

FIG. 2 is an exploded view of the inductor array of FIG. 1.

FIG. 3 is a schematic sectional view of the inductor array of FIG. 1 along the I-I line.

FIG. 4 is a plan view of the inductor array of FIG. 1.

FIG. 5A schematically illustrates a line of a magnetic flux generated from the internal conductor included in the inductor array of FIG. 1.

FIG. 5B schematically illustrates a line of a magnetic flux generated from an internal conductor included in a conventional inductor array.

FIG. 6 is a sectional view schematically showing a section of an internal conductor included in an inductor array according to another embodiment of the present invention.

FIG. 7 is a perspective view of an inductor array according to another embodiment of the present invention.

FIG. 8 is an exploded view of the inductor array of FIG. 7.

FIG. 9 is a schematic sectional view of the inductor array of FIG. 7 along the line II-II.

FIG. 10 is a plan view of the inductor array of FIG. 7.

FIG. 11 is a perspective view of an inductor array according to another embodiment of the present invention.

FIG. 12 is an exploded view of the inductor array of FIG. 11.

FIG. 13 is a schematic sectional view of the inductor array of FIG. 11 along the line III-III.

FIG. 14 is a perspective view of an inductor array according to another embodiment of the present invention.

FIG. 15 is a sectional view schematically showing a section of the inductor array of FIG. 14 along the IV-IV line.

FIG. 16 is a perspective view of an inductor array according to one embodiment of the invention mounted on a mounting substrate.

FIG. 17 is an exploded view of the inductor array of FIG. 16.

FIG. 18 is a sectional view schematically showing a section of the inductor array of FIG. 16 along the V-V line.

FIG. 19A shows, in an L-axis direction, an internal conductor 425A of the inductor array of FIG. 16 by making a part of the base body 10 transparent.

FIG. 19B shows, in the L-axis direction, an internal conductor 425B of the inductor array of FIG. 1 by making a part of the base body 10 transparent.

FIG. 20A is a sectional view schematically showing a section of a winding pattern of an internal conductor included in the inductor array of FIG. 16.

FIG. 20B is a sectional view schematically showing a section of a winding pattern of an internal conductor included in an inductor array according to another embodiment of the present invention.

FIG. 21A schematically shows a line of a magnetic flux generated from a winding portion of an internal conductor included in the inductor array of FIG. 16.

FIG. 21B schematically shows a line of a magnetic flux generated from a winding portion of an internal conductor included in a conventional inductor array.

FIG. 22 is a sectional view schematically showing a section of a winding pattern of an internal conductor included in an inductor array according to another embodiment of the present invention.

FIG. 23 is an exploded view of an inductor array according to another embodiment of the present invention.

FIG. 24 shows, in an L-axis direction, an internal conductor 525A of the inductor array of FIG. 23 by making a part of the base body 10 transparent.

FIG. 25 is an exploded view of an inductor array according to another embodiment of the present invention.

FIG. 26 shows, in an L-axis direction, an internal conductor 625A of the inductor array of FIG. 25 by making a part of the base body 10 transparent.

FIG. 27 is a perspective view of an inductor array according to another embodiment of the present invention.

FIG. 28 is an exploded view of the inductor array of FIG. 27.

FIG. 29 is a perspective view of an inductor array according to another embodiment of the present invention.

FIG. 30 is a sectional view schematically showing a section of the inductor array of FIG. 29 along the VI-VI line.

FIG. 31A shows, in an L-axis direction, an internal conductor 425C of the inductor array of FIG. 29 by making a part of the base body 10 transparent.

FIG. 31B shows, in the L-axis direction, an internal conductor 425D of the inductor array of FIG. 29 by making a part of the base body 10 transparent.

### DESCRIPTION OF THE PREFERRED EMBODIMENTS

The following describes various embodiments of the present invention by referring to the appended drawings as appropriate. The constituents common to more than one drawing are denoted by the same reference signs throughout the drawings. It should be noted that the drawings are not necessarily drawn to an accurate scale for the sake of convenience of explanation. The following embodiments of the present invention do not limit the scope of the claims. The elements described in the following embodiments are not necessarily essential to solve the problem.

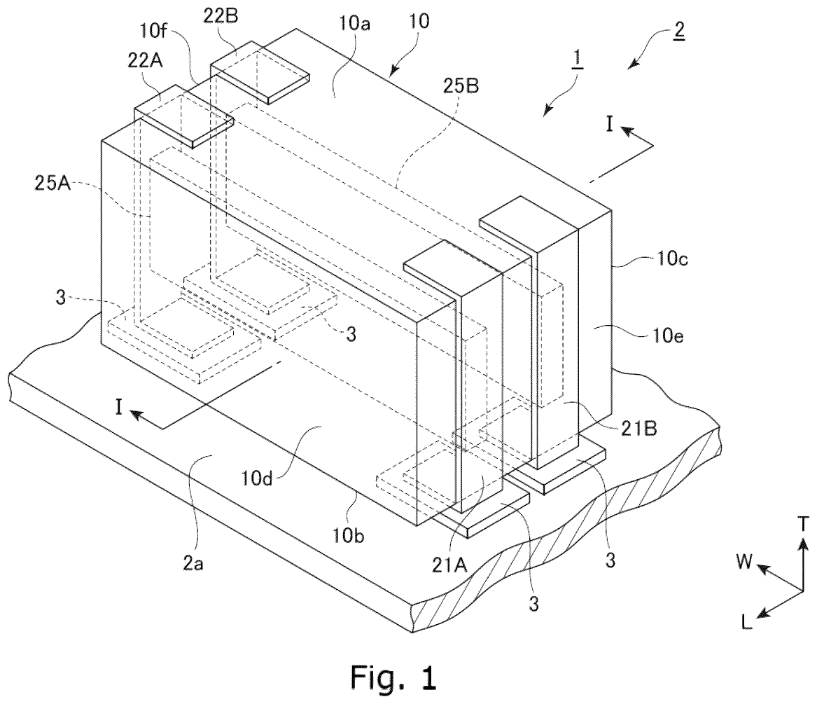

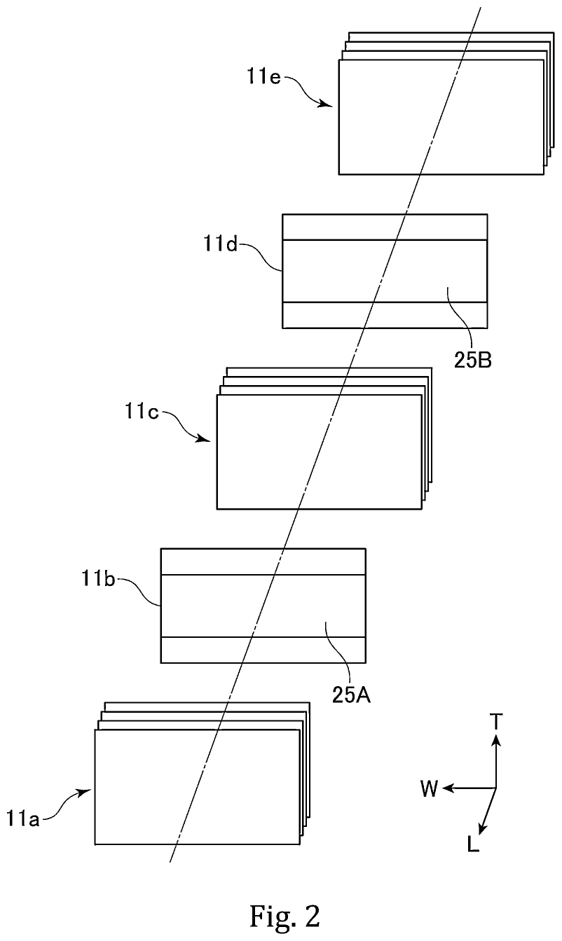

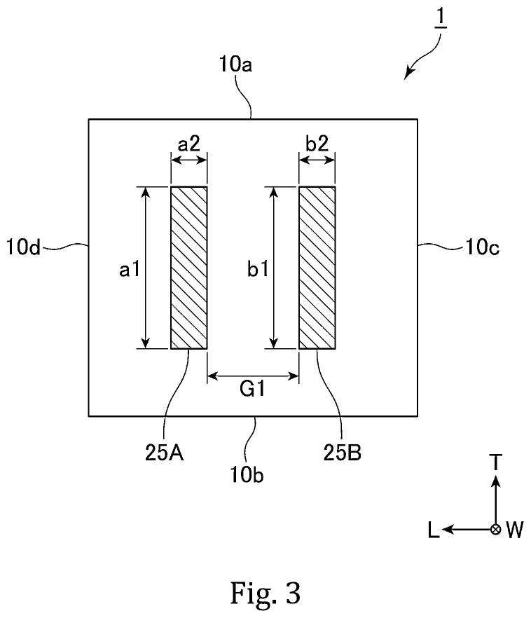

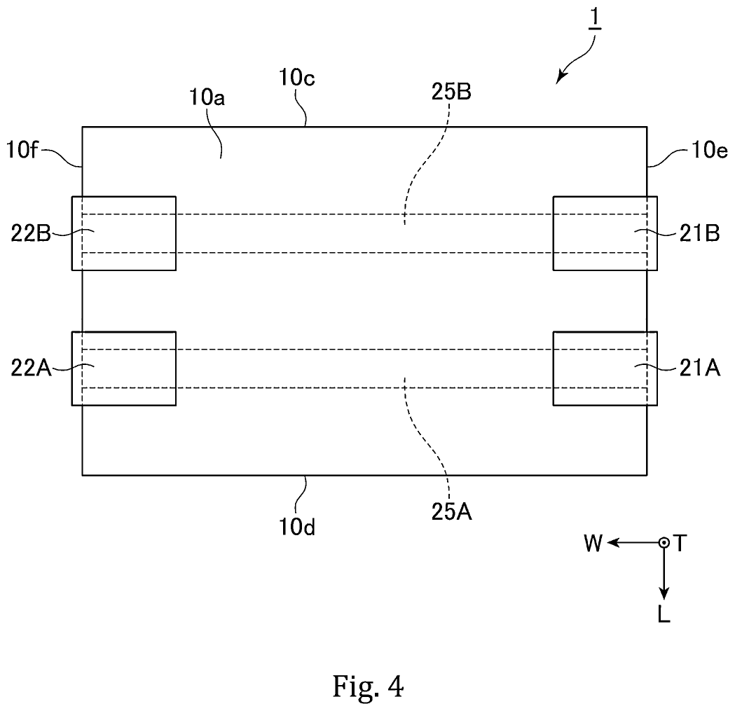

An inductor array 1 according to one or more embodiments of the present invention will be described with reference to FIGS. 1 to 4. FIG. 1 is a perspective view of the inductor array 1 according to one embodiment of the present invention, and FIG. 2 is an exploded view of the inductor array 1. FIG. 3 is a schematic sectional view of the inductor array 1 along the I-I line, and FIG. 4 is a plan view of the inductor array 1.

Each of the drawings shows the L axis, the W axis, and the T axis orthogonal to one another. In this specification, the “length” direction, the “width” direction, and the “thickness” direction of the inductor array 1 are referred to as the L-axis direction, W-axis direction, and T-axis direction in FIG. 1, respectively, unless otherwise construed from the context.

As illustrated, the inductor array 1 includes a base body 10, internal conductors 25A and 25B provided in the base body 10, and external electrodes 21A, 21B, 22A, 22B provided on a surface of the base body 10. The internal conductor 25A is coupled to the external electrode 21A at one end thereof and to the external electrode 22A at the other end thereof. The internal conductor 25B is coupled to the external electrode 21B at one end thereof and to the external electrode 22B at the other end thereof. The internal conductor 25A is disposed at a distance from the internal conductor 25B in the L-axis direction. Thus, the inductor array 1 includes a first inductor including the internal conductor 25A and the external electrodes 21A and 22A, and a second inductor including the internal conductor 25B and the external electrodes 21B and 22B.

The inductor array 1 is used in, for example, a large-current circuit through which a large electric current flows. More specifically, the inductor array 1 may be an inductor used in a DC-to-DC converter.

The inductor array 1 may be mounted on a mounting substrate 2a. The mounting substrate 2a has four lands 3 provided thereon. When the inductor array 1 is mounted on the mounting substrate 2a, the four external electrodes 21A, 21B, 22A, 22B of the inductor array 1 are respectively aligned with or positioned to face the corresponding lands 3. The inductor array 1 may be mounted on the mounting substrate 2 by soldering the external electrodes 21A, 21B, 22A, 22B and the corresponding lands 3, respectively. Thus, a circuit board 2 includes the inductor array 1 and the mounting substrate 2a on which the inductor array 1 is mounted. Various electronic components in addition to the inductor array 1 may be mounted on the mounting substrate 2a.

The circuit board 2 can be installed in various electronic devices. Electronic devices in which the circuit board 2 may be installed include smartphones, tablets, game consoles, servers, electrical components of automobiles, and various other electronic devices. The inductor array 1 may be a built-in component embedded in the mounting substrate 2a.

Since the inductor array 1 is formed as a single chip in which the first inductor with the internal conductor 25A and the external electrodes 21A, 22A and the second inductor with the internal conductor 25B and the external electrodes 21B, 22B are included, it is particularly suitable for small electronic devices that require high-density mounting of electronic components.

In the illustrated embodiment, the base body 10 may have a rectangular parallelepiped shape. In one embodiment of the invention, the base body 10 has a length (the dimension in the L-axis direction) of 0.6 mm to 10 mm, a width (the dimension in the W-axis direction) of 0.2 mm to 10 mm, and a height (the dimension in the T-axis direction) of 0.2 mm to 10 mm. The base body 10 has a first region situated on a positive side in the L-axis direction with respect to a predetermined boundary on the L-axis, and a second region situated on a negative side with respect to the boundary in the L-axis direction. The first region includes the internal conductor 25A, and the second region includes the internal conductor 25B. In this manner, the base body 10 has a plurality of regions, each of which has a single inductor. The dimension of such a region of the base body 10 in the L-axis direction containing a single inductor is 0.15 mm to 5.0 mm. The dimensions of the base body 10 are not limited to those specified herein. The term “rectangular parallelepiped” or “rectangular parallelepiped shape” used herein is not intended to mean solely “rectangular parallelepiped” in a mathematically strict sense.

The base body 10 has a first principal surface 10a, a second principal surface 10b, a first end surface 10c, a second end surface 10d, a first side surface 10e, and a second side surface 10f. These six surfaces define the outer periphery of the base body 10. The first principal surface 10a and the second principal surface 10b are opposed to each other, the first end surface 10c and the second end surface 10d are opposed to each other, and the first side surface 10e and the second side surface 10f are opposed to each other. The first end surface 10c and the second end surface 10d connect the first principal surface 10a and the second principal surface 10b, and also connect the first side surface 10e and the second side surface 10f. Based on the position of the mounting substrate 2a, the first principal surface 10a lies on the top side of the base body 10, and therefore, the first principal surface 10a may be herein referred to as the “top surface,” and the second principal surface 10b may be herein referred to as the “bottom surface.”

The inductor array 1 is disposed such that the first principal surface 10a or the second principal surface 10b faces the mounting substrate 2a. One of the first principal surface 10a and the second principal surface 10b that faces the mounting substrate 2a is herein referred to as a “mounting surface.” In the illustrated embodiment, the second principal surface 10b faces the mounting substrate 2a, so this second principal surface 10b is the “mounting surface.” Thus, the second principal surface 10b may also be herein referred to as the “mounting surface 10b.” Since the “mounting surface” of the base body 10 is the surface facing the mounting substrate 2a, any surface other than the second principal surface 10b may be the mounting surface. All the external electrodes 21A, 22A, 21B, and 22B provided in the inductor array 1 at least partially contact the mounting surface of the base body 10. In the embodiment shown in FIG. 1, the external electrodes 21A, 22A, 21B, and 22B are all partially in contact with the first and second principal surfaces 10a and 10b so either the first principal surface 10a or the second principal surface 10b can be used as the mounting surface.

In the illustrated embodiment, the first and second principal surfaces 10a and 10b are parallel to the LW plane, the first and second end surfaces 10c and 10d are parallel to the WT plane, and the first and second side surfaces 10e and 10f are parallel to the TL plane.

The top-bottom direction of the inductor array 1 refers to the top-bottom direction in FIG. 1. The thickness direction of the inductor array 1 or the base body 10 may be the direction perpendicular to at least one of the top surface 10a or the mounting surface 10b. The length direction of the inductor array 1 or the base body 10 may be the direction perpendicular to at least one of the first end surface 10c or the second end surface 10d. The width direction of the inductor array 1 or the base body 10 may be the direction perpendicular to at least one of the first side surface 10e or the second side surface 10f. The width direction of the inductor array 1 or the base body 10 may be the direction perpendicular to the thickness direction and the length direction of the inductor array 1 or the base body 10.

In the illustrated embodiment, the external electrode 22A is attached to the base body 10 at a position spaced apart from the external electrode 21A in the W-axis direction, and the external electrode 21B is attached to the base body 10 at a position spaced apart from the external electrode 21A in the L-axis direction. The external electrode 22B is attached to the base body 10 at a position spaced apart from the external electrode 22A in the L-axis direction and spaced apart from the external electrode 21B in the W-axis direction. In the illustrated embodiment, the external electrodes 21A and 21B are provided in contact with the mounting surface 10b, the first side surface 10e, and the top surface 10a of the base body 10, and the external electrodes 22A and 22B are provided in contact with the mounting surface 10b, the second side surface 10f, and the top surface 10a of the base body 10. The external electrodes 21A and 21B may be provided on the base body 10 such that they are in contact with the mounting surface 10b and the first side surface 10e but not with the top surface 10a. The external electrodes 22A and 22B may be provided on the base body 10 such that they are in contact with the mounting surface 10b and the second side surface 10f but not with the top surface 10a. The shape and arrangement of the external electrodes 21A, 22B, 22A, and 22B are not limited to those explicitly described herein. The external electrodes 21A, 21B, 22A, 22B may have the same shape as each other or may have different shapes from each other. Any pair selected from among the external electrodes 21A, 21B, 22A, and 22B may have the same shape as each other.

The base body 10 is made of a magnetic material. The magnetic material for the base body 10 may contain a plurality of metal magnetic particles. The metal magnetic particles contained in the magnetic material for the base body 10 are, for example, particles of (1) a metal such as Fe or Ni, (2) a crystalline alloy such as an Fe—Si—Cr alloy, an Fe—Si—Al alloy, or an Fe—Ni alloy, (3) an amorphous alloy such as an Fe—Si—Cr—B—C alloy or an Fe—Si—Cr—B alloy, or (4) a mixture thereof. The composition of the metal magnetic particles contained in the base body 10 is not limited to those described above. For example, the metal magnetic particles contained in the base body 10 may be particles of a Co—Nb—Zr alloy, an Fe—Zr—Cu—B alloy, an Fe—Si—B alloy, an Fe—Co—Zr—Cu—B alloy, an Ni—Si—B alloy, or an Fe—Al—Cr alloy. The Fe-based metal magnetic particles contained in the base body 10 may contain 80 wt % or more Fe. An insulating film may be formed on the surface of each of the metal magnetic particles. The insulating film may be an oxide film made of an oxide of the above metals or alloys. The insulating film provided on the surface of each of the metal magnetic particles may be, for example, a silicon oxide film provided by the sol-gel coating process.

In one or more embodiments, the average particle size of the metal magnetic particles in the base body 10 is from 1.0 μm to 20 μm. The average particle size of the metal magnetic particles contained in the base body 10 may be smaller than 1.0 μm or larger than 20 μm. The base body 10 may contain two or more types of metal magnetic particles having different average particle sizes.

In the base body 10, the metal magnetic particles may be bonded to each other with an oxide film formed by oxidation of an element included in the metal magnetic particles during a manufacturing process. The base body 10 may contain a binder in addition to the metal magnetic particles. When the base body 10 contains a binder, the metal magnetic particles are bonded to each other by the binder. The binder in the base body 10 may be formed, for example, by curing a thermosetting resin that has an excellent insulation property. Examples of a material for such a binder include an epoxy resin, a polyimide resin, a polystyrene (PS) resin, a high-density polyethylene (HDPE) resin, a polyoxymethylene (POM) resin, a polycarbonate (PC) resin, a polyvinylidene fluoride (PVDF) resin, a phenolic resin, a polytetrafluoroethylene (PTFE) resin, or a polybenzoxazole (PBO) resin.

In one or more embodiments of the invention, the relative magnetic permeability of the base body 10 is, for example, 100 or less. In one or more embodiments of the invention, the relative magnetic permeability of the base body 10 is, for example, 30 or greater. When the inductor array 1 is used in a high frequency circuit, the relative magnetic permeability of the base body 10 may be reduced. For example, when the inductor array 1 operates at a frequency of about 100 MHz, the lower limit of the relative magnetic permeability of the base body 10 may be 20 or greater. When the inductor array 1 operates at a higher frequency band, the lower limit of the relative magnetic permeability of the base body 10 may be 10 or greater. In one or more embodiments of the invention, the relative magnetic permeability of the base body 10 is, for example, in the range of 30 to 100 (both inclusive). The base body 10 may be configured to have a relative magnetic permeability in the range of 30 to 100 in all the regions. As described above, the inductor array 1 may be used in DC to DC converters where a low inductance is required. When the base body 10 has a relative magnetic permeability of 100 or less, it is easy to achieve a required low inductance. When the base body 10 has a relative magnetic permeability of 100 or less, it is also easy to achieve high current characteristics. When the base body 10 has a relative magnetic permeability of 100 or less, it is also easy to achieve high insulation properties. When the base body 10 has a relative magnetic permeability of 100 or less, it is possible to reduce the chance of magnetic saturation. Therefore there is no need to provide a magnetic gap in the base body 10 to improve the DC superposition characteristics.

As mentioned above, the relative magnetic permeability of the base body 10 of the inductor array 1 takes a small value, such as 100 or smaller, so that the inductance L of each line of inductor included in the inductor array 1 also takes a small value. Since the inductance of each line of inductor is low, magnetic saturation is unlikely to occur in the inductor array 1. As a result, it is possible to let a large current flow through each line of inductor included in the inductor array 1. Accordingly, in one or more embodiments of the present invention, each line of inductor in the inductor array 1 can achieve increased energy density Ed, which is expressed as the product of the inductance L of the inductor and the result of dividing the square of the current I flowing through the inductor by the volume V of the inductor (Ed=L×I²/V). For example, when the inductance L of each line of inductor in the inductor array 1 is less than 100 nH, the Ed can be 1500 nH·A²/mm³. Alternatively, when the inductance L of each line of inductor in the inductor array 1 is less than 50 nH, the Ed can be 2000 nH·A²/mm³. When the inductance L of each line of inductor in the inductor array 1 is less than 25 nH, the Ed can be 2500 nH·A²/mm³.

The internal conductor 25A and the internal conductor 25B are provided inside the base body 10. In the illustrated embodiment, the internal conductor 25A is exposed at one end thereof to the outside of the base body 10 from the first side surface 10e and is connected to the external electrode 21A at the one end. The internal conductor 25A is also exposed at the other end thereof to the outside of the base body 10 from the second side surface 10f and is connected to the external electrode 22A at the other end. In this manner, the internal conductor 25A is connected at one end thereof to the external electrode 21A and connected at the other end thereof to the external electrode 22A. Similarly, the internal conductor 25B is exposed at one end thereof to the outside of the base body 10 from the first side surface 10e and is connected to the external electrode 21B at the one end. The internal conductor 25B is also exposed at the other end thereof to the outside of the base body 10 from the second side surface 10f and is connected to the external electrode 22B at the other end. In this manner, the internal conductor 25B is connected at one end thereof to the external electrode 21B and connected at the other end thereof to the external electrode 22B. In this way, to connect the internal conductors 25A and 25B to the external electrodes, the internal conductors 25A and 25B are not directly connected to a first surface, but are connected to the first surface outside the base body 10 via the external electrodes 21A, 22A, 21B and 22B formed on the first and second side surfaces. Therefore the volume of the base body 10 can be increased relative to the overall volume of the inductor array 1. Consequently it is possible to increase the ratio of the volume of the base body 10 made of a magnetic material in the inductor array 1, and thus to increase the saturation magnetic flux density of the base body 10.

As shown in FIG. 4, the internal conductor 25A extends linearly from the external electrode 21A to the second external electrode 22A in plan view (as viewed from the T axis). Stated differently, the internal conductor 25A has no parts facing each other in the base body 10 in a plan view. Herein, when the internal conductor 25A has no parts facing each other in the base body 10 in a plan view, it can be said that the internal conductor 25A extends linearly from the external electrode 21A to the external electrode 22A. Thus, compared with conventional inductors that have internal conductors with parts facing each other in plan view, the insulation reliability (withstand voltage) can be increased without changing the volume resistivity of the base body 10. The internal conductor 25A may be disposed on a straight line drawn from the external electrode 21A to the external electrode 22A. In the illustrated embodiment, the internal conductor 25A has a rectangular parallelepiped shape. The internal conductor 25A may include a plurality of conductor layers arranged in parallel between the external electrode 21A and the external electrode 22A. All of these conductor layers extend linearly from the external electrode 21A to the external electrode 22A and are shaped similarly to each other. Each of the plurality of conductor layers included in the internal conductor 25A has no parts that are disposed to be opposed to each other in the base body 10. Since the plurality of conductor layers are shaped similarly to each other, among the plurality of conductor layers, there is no difference in potential between such parts that are opposed to each other in the base body 10. Therefore, even when the internal conductor 25A is formed of a plurality of conductor layers, it is possible to make the insulation reliability (withstand voltage) required of the base body 10 same as that of the internal conductor 25A formed of a single conductor layer. The plurality of conductor layers included in the internal conductor 25A may be connected to each other in the base body 10. The internal conductor 25A and the internal conductor 25B may be formed of a plurality of conductors that are connected to each other by means other than through holes. The internal conductor 25A and the internal conductor 25B may each include a plurality of conductors that are not connected to each other in the base body 10, but are connected by the external electrodes 21A and 22A and the external electrodes 21B and 22B.

In the illustrated embodiment, the internal conductor 25A has a rectangular parallelepiped shape. Therefore when a voltage is applied between the external electrode 21A and the external electrode 22A, the current flows in the direction of the W axis in the internal conductor 25A.

In one or more embodiments of the invention, the internal conductor 25B may have the same shape as the internal conductor 25A. For example, the internal conductor 25B may extend linearly from the external electrode 21B to the second external electrode 22B in plan view (as viewed from the T axis). In the illustrated embodiment, the internal conductor 25B has a rectangular parallelepiped shape. Therefore when a voltage is applied between the external electrode 21B and the external electrode 22B, the current flows in the direction of the W axis in the internal conductor 25B. The shape of the internal conductor 25B in a planar view (the shape when seen in the L-axis direction) may be the same as the shape of the internal conductor 25A in a planar view (the shape when seen in the L-axis direction). Since the internal conductors 25A and 25B have the same shape, the inductor array 1 can easily achieve uniform electrical characteristics among the lines included therein.

As shown in FIG. 2, the inductor array 1 may have a multilayer structure of multiple magnetic layers stacked together. In FIG. 2, the external electrodes 21A, 22A, 21B, and 22B are not shown for convenience of description. In the illustrated embodiment, the base body 10 includes magnetic layers 11a to 11e. Each of the magnetic layers 11a to 11e is made of a magnetic material. The base body 10 includes the magnetic layer 11a, the magnetic layer 11b, the magnetic layer 11c, the magnetic layer 11d, and the magnetic layer 11e, which are stacked together in the stated order from the negative side to the positive side in the L-axis direction. As shown, the magnetic layers 11a, 11c and 11e may each include a plurality of magnetic layers. Likewise, the magnetic layers other than the magnetic layers 11a, 11c and 11e may each include a plurality of magnetic layers. The magnetic layer 11a and the magnetic layer 11e are disposed so as to cover the internal conductors 25A and 25B on both sides in the L-axis direction, and thus these magnetic layers may be referred to as the cover layers.

The internal conductor 25A is provided on one surface of the magnetic layer 11b, and the internal conductor 25B is provided on one surface of the magnetic layer 11d. More specifically, the internal conductor 25A is provided on one of the surfaces of the magnetic layer 11b intersecting the L axis, or the positive-side surface in the L-axis direction, and the internal conductor 25B is provided on one of the surfaces of the magnetic layer 11d intersecting the L axis, or the positive-side surface in the L-axis direction. The internal conductors 25A and 25B are formed by, for example, printing a conductive paste made of a highly conductive metal or alloy on each magnetic layer by screen printing. The electrically conductive material contained in the conductive paste may be Ag, Cu, or alloys thereof. In the embodiment shown, the internal conductor 25A is provided on the magnetic layer 11b and the internal conductor 25B is provided on the magnetic layer 11d, which is a different magnetic layer from the magnetic layer 11b. The internal conductors 25A and 25B may be, however, provided on the same magnetic layer. The internal conductors 25A and 25B may be formed using other methods and materials. For example, the internal conductors 25A and 25B may be formed by sputtering, ink-jetting, or other known methods.

With further reference to FIG. 3, the arrangement and sectional shape of the internal conductors 25A and 25B will be further described. FIG. 3 is a sectional view schematically showing the section of the inductor array 1 along the I-I line. FIG. 3 shows a section of the internal conductor 25A resulting from cutting the internal conductor 25A along a plane perpendicular to the W-axis direction. Since the current flows in the W-axis direction through each of the internal conductors 25A and 25B as described above, FIG. 3 illustrates a section of the internal conductors 25A and 25B obtained by cutting them along a plane orthogonal to the direction of current flowing through the internal conductors 25A and 25B. As used herein, the terms “parallel,” “orthogonal” or “perpendicular” are not intended to mean solely “parallel,” “orthogonal” or “perpendicular” in a mathematically strict sense.

In one or more embodiments of the invention, the internal conductor 25B is disposed at a distance G1 from the internal conductor 25A in the L-axis direction. In other words, the spacing between the internal conductor 25A and the internal conductor 25B in the L-axis direction is G1. The spacing G1 between the internal conductor 25A and the internal conductor 25B is the distance in the L-axis direction between an end of the internal conductor 25A situated on the negative side of the L-axis direction and an end of the internal conductor 25B situated on the positive side of the L-axis direction. In one or more embodiments of the invention, the spacing G1 between the internal conductors 25A and 25B is 0.3 mm or less. When magnitudes of currents flowing through the internal conductor 25A and the internal conductor 25B and magnitudes of voltages applied to the internal conductor 25A and the internal conductor 25B are the same or close to each other, there will be no large potential difference between the internal conductor 25A and the internal conductor 25B and therefore the distance between the internal conductor 25A and the internal conductor 25B can be made smaller. When the magnitudes of currents flowing through the internal conductor 25A and the internal conductor 25B and the magnitudes of voltages applied to the internal conductor 25A and the internal conductor 25B are the same or close to each other, the spacing G1 between the internal conductor 25A and the internal conductor 25B may be 0.1 mm or more, such as about 0.12 mm.

As shown in FIG. 3, the section of the internal conductor 25A cut along the plane perpendicular to the direction of the current flowing through the internal conductor 25A has a dimension a2 in a reference direction and a dimension a1 in a direction perpendicular to the reference direction. In the illustrated embodiment, the reference direction coincides with the L-axis direction, and the direction perpendicular to the reference direction of the section of the internal conductor 25A cut along the plane perpendicular to the current flowing direction coincides with the T-axis direction. The ratio of a1 to a2 (a1/a2) is herein defined as a first aspect ratio. In one or more embodiments of the invention, the first aspect ratio is greater than one (1). Since the internal conductor 25A is disposed away from the internal conductor 25B in the L-axis direction, the internal conductor 25A is separated from the internal conductor 25B in the reference direction.

Similarly, the section of the internal conductor 25B cut along a plane perpendicular to the direction of the current flowing through the internal conductor 25B has a dimension b2 in a reference direction and a dimension b1 in a direction perpendicular to the reference direction. In the illustrated embodiment, the reference direction coincides with the L-axis direction, and the direction perpendicular to the reference direction of the section of the internal conductor 25B cut along the plane perpendicular to the current flowing direction coincides with the T-axis direction. The ratio of b1 to b2 (b1/b2) is defined as a second aspect ratio herein. In one or more embodiments of the invention, the second aspect ratio of the internal conductor 25B is greater than one (1).

As mentioned above, the internal conductor 25A may include multiple conductor layers arranged in parallel between the external electrode 21A and the external electrode 22A. In this case, the distance between an outer end of a conductor layer situated at one end (left end in FIG. 3) in the reference direction (L-axis direction) among the plurality of conductor layers forming the internal conductor 25A and an outer end of a conductor layer situated at the other end (right end in FIG. 3) in the reference direction (L-axis direction) among the plurality of conductor layers forming the internal conductor 25A may be defined as the dimension a2, which is the dimension of the section of the internal conductor 25A in the reference direction (L-axis direction). Similarly, when the internal conductor 25B includes multiple conductor layers arranged in parallel between the external electrode 21B and the external electrode 22B, the distance between an outer end of a conductor layer situated at one end (left end in FIG. 3) in the reference direction (L-axis direction) among the plurality of conductor layers forming the internal conductor 25B and an outer end of a conductor layer situated at the other end (right end in FIG. 3) in the reference direction (L-axis direction) among the plurality of conductor layers forming the internal conductor 25B may be defined as the dimension b2, which is the dimension of the section of the internal conductor 25B in the reference direction (L-axis direction).

FIG. 3 shows the sections of the internal conductors 25A and 25B cut along a plane that is parallel to the LT plane and passes the center of the base body 10. The sections of the internal conductors 25A and 25B shown in FIG. 3 are orthogonal to the direction of the current flowing through the internal conductors 25A and 25B, respectively, as described above. In one or more embodiments of the invention, not only for the sections of the internal conductors 25A and 25B cut along the plane that is parallel to the LT plane and passes the center of the base body 10 as illustrated in FIG. 3, but also for any section of the internal conductor 25A orthogonal to the direction of the current flowing through the internal conductor 25A, the first aspect ratio is greater than one, and for any section of the internal conductor 25B orthogonal to the direction of the current flowing through the internal conductor 25B, the second aspect ratio is greater than one. In one or more embodiments of the invention, for the entire length of the internal conductors 25A and 25B along the direction of the current flowing (W-axis direction in the embodiment shown) through the internal conductors 25A and 25B, the first and second aspect ratios are greater than one for the section orthogonal to the direction of the current flowing.

The section of the internal conductor 25A cut along the plane perpendicular to the direction of the current flowing through the internal conductor 25A may be herein simply referred to as a “section of the internal conductor 25A” without specifying the cut plane for brevity of description. Similarly, the section of the internal conductor 25B cut along the plane perpendicular to the direction of the current flowing through the internal conductor 25B may be herein simply referred to as a “section of the internal conductor 25B” without specifying the cut plane for brevity of description.

In the illustrated embodiment, since the first aspect ratio is greater than one, the dimension a1 of the section of the internal conductor 25A in the direction perpendicular to the L-axis direction is greater than the dimension a2 in the L-axis direction. Similarly, since the second aspect ratio is greater than one, the dimension b1 of the section of the internal conductor 25B in the direction perpendicular to the L-axis direction is greater than the dimension b2 in the L-axis direction. In the illustrated embodiment, the first aspect ratio and the second aspect ratio are approximately 4. Each of the first and second aspect ratios may be greater than 1.1, 1.2, 1.3, 1.4, 1.5, 2.0, 3.0, 4.0, 5.0, or 10.0. The first and second aspect ratios may be the same or different.

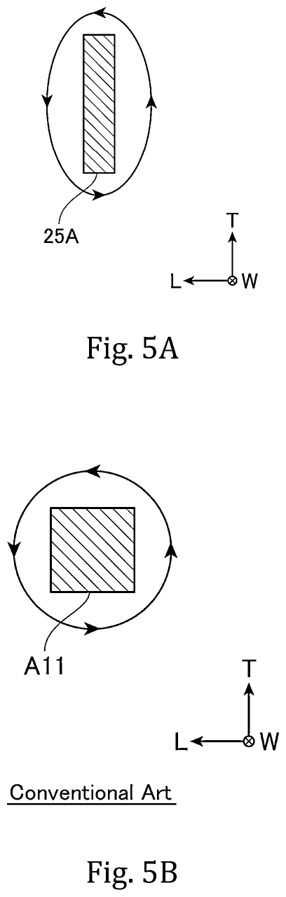

Next, with further reference to FIGS. 5A and 5B, the magnetic flux generated around the internal conductor 25A due to a change in the current flowing through the internal conductor 25A will be now described. FIG. 5A schematically illustrates a line of a magnetic flux generated around the internal conductor 25A due to a change in the electric current flowing through the internal conductor 25A, and FIG. 5B schematically illustrates a line of a magnetic flux generated around a conventional internal conductor due to a change in electric current flowing through the internal conductor. FIG. 5B shows a section of an internal conductor A11 cut along the plane perpendicular to the direction of current flowing through the internal conductor A11. The section of this internal conductor A11 has a square shape with the same area as the section of the internal conductor 25A shown in FIG. 5A. The sections of conventional internal conductors typically have a square or circular shape in order to reduce the Rdc of the internal conductors.

As shown in FIG. 5A, the magnetic flux generated around the internal conductor 25A when the current flowing through the internal conductor 25A changes tends to face perpendicularly to the L-axis direction (the T-axis direction in FIG. 5A) because the first aspect ratio of the internal conductor 25A is greater than one. Whereas the direction of the magnetic flux generated around the conventional internal conductor A11, which has a square cross section, does not tend to distribute in any particular direction as shown in FIG. 5B. Therefore, by making the first aspect ratio of the internal conductor 25A greater than one, the magnetic flux generated around the internal conductor 25A due to a change in the current flowing through the internal conductor 25A may be unlikely to reach other internal conductor(s) (e.g., the internal conductor 25B) that is (are) situated adjacent to the internal conductor 25A in the L-axis direction, when compared with a case where a conventional internal conductor having a first aspect ratio of 1 or less is employed. Consequently, by making the first aspect ratio of the internal conductor 25A greater than one, the magnetic coupling between the internal conductor 25A and another internal conductor (e.g., the internal conductor 25B) adjacent to the internal conductor 25A in the L-axis direction can be lessened. Since the magnetic coupling between the internal conductors 25A and 25B is lessened in this manner, the absolute value of the coefficient of the coupling between the internal conductors 25A and 25B can be 0.15 or less in one or more embodiments of the invention. In one or more embodiments of the invention, the absolute value of the coefficient of the coupling between the internal conductors 25A and 25B can be 0.15 or less even with a spacing of 0.3 mm or less between the internal conductors 25A and 25B. In one or more embodiments of the invention, the absolute value of the coefficient of the coupling between the internal conductors 25A and 25B is 0.15 or less, so that each of the internal conductors 25A and 25B can stably exhibit its own characteristics without being disturbed by electromagnetic interference from the other internal conductor. Since the internal conductors 25A and 25B included in the inductor array 1 can each avoid electromagnetic interference from the other internal conductor, the internal conductors 25A and 25B can each exhibit their own characteristics even with a small pitch (for example, 0.2 mm or less) of the wirings of the circuit having the inductor array 1 installed therein. For example, in a circuit where the inductor array 1 is connected to a plurality of semiconductor devices (for example, power transistors), the internal conductors 25A and 25B can each provide an independent power source to each of the semiconductor devices.

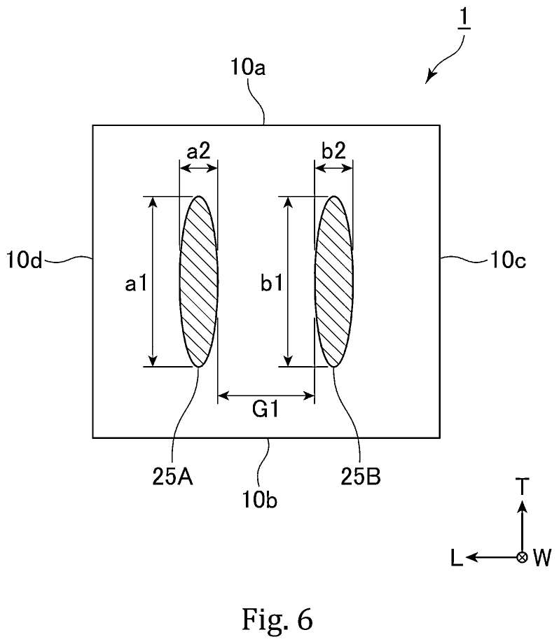

An inductor array according to another embodiment to which the invention is applicable will be now described with reference to FIGS. 6 to 15.

Next, a description is given of a modification example of the internal conductors 25A and 25B with further reference to FIG. 6. In the embodiment shown in FIG. 6, the internal conductors 25A and 25B have a rounded section. In other words, the internal conductors 25A and 25B have a section the outer edge of which is defined only by a curved line. The internal conductors 25A and 25B may have a section shaped like an ellipse as shown in FIG. 5 or any other shapes (for example, an oval). Since the internal conductors 25A and 25B have a rounded section, the magnetic flux generated around the internal conductors 25A and 25B follows a magnetic path closer to the center of the section of the respective internal conductors 25A and 25B. This can lessen the magnetic coupling between the internal conductors 25A and 25B.

The shape of the section of the internal conductors 25A and 25B is not limited to the above-described shapes. The internal conductors 25A and 25B may have a section shaped like, for example, a polygon other than a rectangle. The internal conductors 25A and 25B may have a beveled rectangular section.

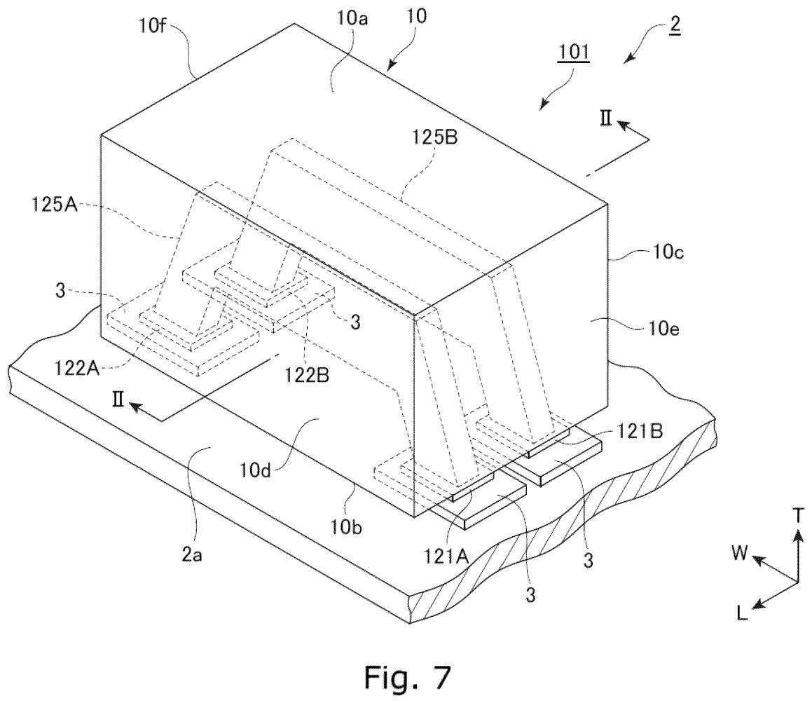

An inductor array 101 according to one or more embodiments of the invention will now be described with reference to FIGS. 7 to 10. The inductor array 101 shown in FIGS. 7 to 10 differs from the inductor array 1 in that it has internal conductors 125A and 125B instead of the internal conductors 25A and 25B, respectively, and external electrodes 121A, 122A, 121B, and 122B instead of the external electrodes 21A, 22A, 21B, and 22B, respectively. The following description does not mention the similarities between the inductor arrays 101 and 1.

In the illustrated embodiment, the external electrodes 121A, 122A, 121B, 122B are all provided on the second principal surface 10b of the base body 10. The shapes of the external electrodes 121A, 122A, 121B, 122B are not limited to those shown. For example, the external electrodes 121A and 121B may be provided on the base body 10 such that they are in contact with the second principal surface 10b and additionally the first side surface 10e. The external electrodes 122A and 122B may be provided on the base body 10 such that they are in contact with the second principal surface 10b and additionally the second side surface 10f.

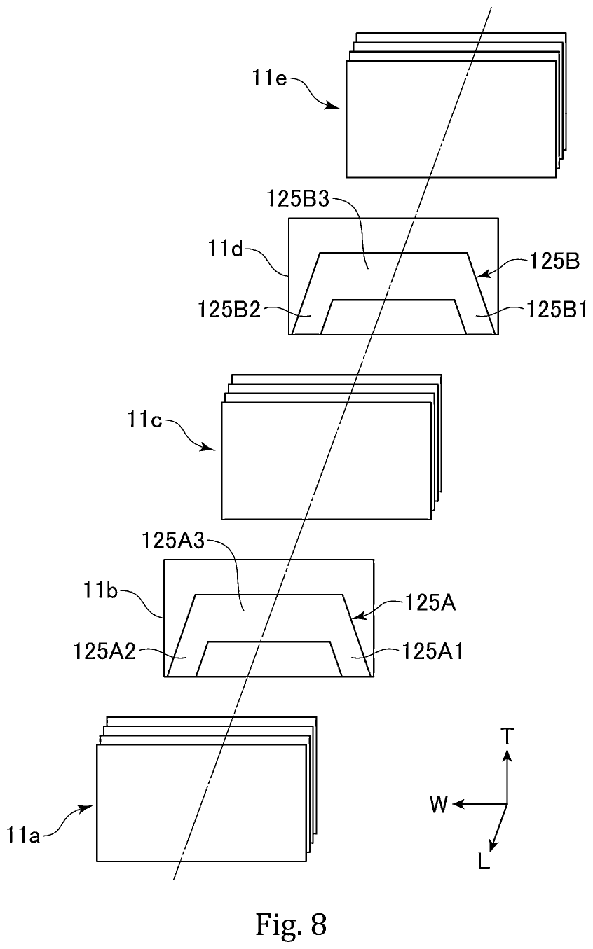

In the embodiment illustrated, the internal conductor 125A is provided in the base body 10 so as to connect between the external electrode 121A and the external electrode 122A. As shown in FIG. 8, the internal conductor 125A is provided on one of the surfaces of the magnetic layer 11b intersecting the L-axis, or the positive-side surface in the L-axis direction. The internal conductor 125A includes a first portion 125A1, a second portion 125A2, and a third portion 125A3. The first portion 121A1 is connected to the external electrode 121A at one end and extends in an angled direction with respect to the T axis, and the second portion 125A2 is connected to the external electrode 122A at one end and extends in an angled direction with respect to the T axis. The third portion 125A3 extends in the W-axis direction and connects the other end of the first portion 121A1 with the other end of the second portion 121A2.

In the embodiment illustrated, the internal conductor 125B is provided in the base body 10 so as to connect between the external electrode 121B and the external electrode 122B, and has the same shape as the internal conductor 125A. More specifically, as shown in FIG. 8, the internal conductor 125B is provided on one of the surfaces of the magnetic layer 11d intersecting the L-axis, or the positive-side surface in the L-axis direction. The internal conductor 125B includes a first portion 125B1, a second portion 125B2, and a third portion 125B3. The first portion 121B1 is connected to the external electrode 121B at one end and extends in an angled direction with respect to the T axis, and the second portion 125B2 is connected to the external electrode 122B at one end and extends in an angled direction with respect to the T axis. The third portion 125B3 extends in the W-axis direction and connects the other end of the first portion 121B1 with the other end of the second portion 121B2.

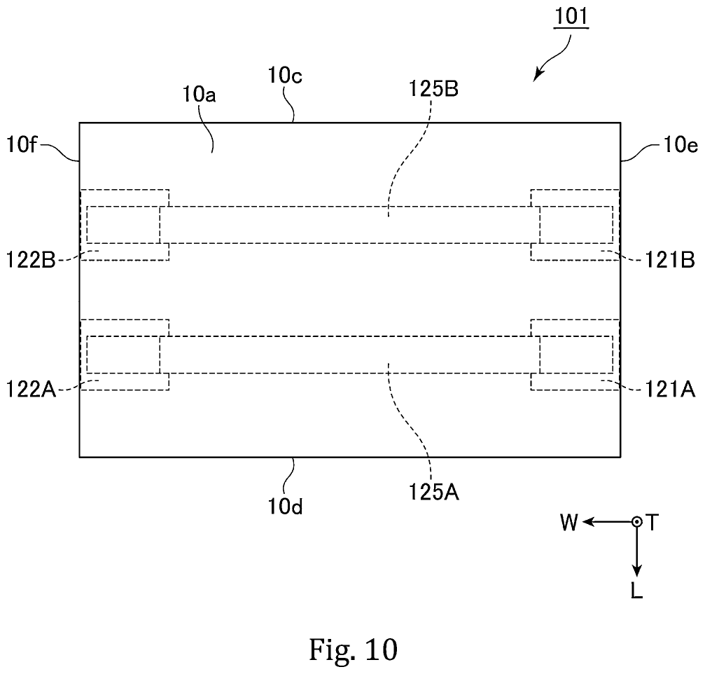

As shown in FIG. 10, the internal conductor 125A extends linearly from the external electrode 121A to the second external electrode 122A in plan view (as viewed from the T axis). The internal conductor 125B extends linearly from the external electrode 121B to the second external electrode 122B in plan view (as viewed from the T axis). In this way, the internal conductors 125A and 125B have no parts facing each other in the base body 10 in plan view. Since the internal conductors 125A and 125B have no parts facing each other in the base body 10 in plan view, the inductor array 101 can achieve improved insulation reliability (withstand voltage) without changing the volume resistivity of the base body 10 compared with a case where conventional inductors that have internal conductors with parts facing each other in plan view are employed.

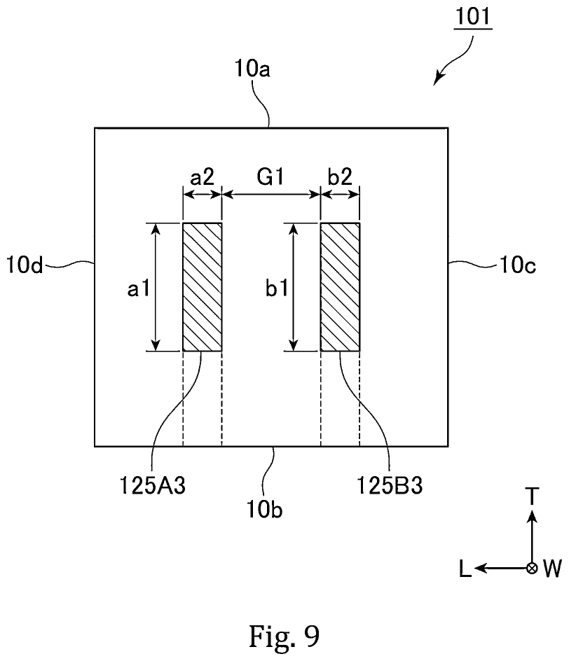

FIG. 9 is a schematic sectional view of the inductor array 101 along the line II-II. FIG. 9 shows sections of the internal conductors 125A and 125B cut along a plane that is parallel to the LT plane and passes the center of the base body 10. In the third portion 125A3 of the internal conductor 125A and the third portion 125B3 of the internal conductor 125B, the current flows in the W-axis direction. Thus, FIG. 9 shows an example of sections of the internal conductors 125A and 125B cut along the plane perpendicular to the direction of current flowing through the internal conductors 125A and 125B. The first aspect ratio of the internal conductor 125A is defined in the same way as the first aspect ratio of the internal conductor 25A, and the second aspect ratio of the internal conductor 125B is defined in the same way as the second aspect ratio of the internal conductor 25B. Specifically, the section of the internal conductor 125A cut along the plane perpendicular to the direction of the current flowing through the internal conductor 125A has a dimension a2 in the L-axis direction, and has a dimension a1 in a direction perpendicular to the L-axis direction. Here, the ratio of a1 to a2 (a1/a2) is defined as the first aspect ratio of the internal conductor 125A. Similarly, the section of the internal conductor 125B cut along the plane perpendicular to the direction of the current flowing through the internal conductor 125B has a dimension b2 in the L-axis direction, and has a dimension b1 in a direction perpendicular to the L-axis direction. Here, the ratio of b1 to b2 (b1/b2) is defined as the second aspect ratio of the internal conductor 125B. As mentioned above, in one or more embodiments of the invention, the first aspect ratio of the internal conductor 125A is greater than one (1). In one or more embodiments of the invention, the second aspect ratio of the internal conductor 125B is greater than one (1).

The cutting plane for defining the first aspect ratio of the internal conductor 125A is not limited to the plane parallel to the LT plane shown in FIG. 9. The current flowing through the internal conductor 125A runs through the first portion 121A1 and the second portion 121A2 in the TW plane in the diagonal directions to the T-axis and W-axis, respectively. Thus when determining the first aspect ratio of the section of the first portion 121A1 or second portion 121A2, used are dimensions of sections of the internal conductor 125A cut in a plane parallel to the L-axis direction and diagonal to the W-axis direction and T-axis direction, respectively. The cutting plane for defining the second aspect ratio of the internal conductor 125B is not limited to the plane parallel to the LT plane shown in FIG. 9. The current flowing through the internal conductor 125B runs through the first portion 121B1 and the second portion 121B2 in the TW plane in the diagonal directions to the T-axis and W-axis, respectively. Thus when determining the second aspect ratio of the section of the first portion 121B1 or second portion 121B2, used are dimensions of sections of the internal conductor 125B cut in a plane parallel to the L-axis direction and diagonal to the W-axis direction and T-axis direction, respectively. In one or more embodiments of the invention, any section of the internal conductor 125A orthogonal to the direction of the current flowing through the internal conductor 125A has a first aspect ratio of greater than one. In one or more embodiments of the invention, any section of the internal conductor 125B orthogonal to the direction of the current flowing through the internal conductor 125B has a second aspect ratio of greater than one. In one or more embodiments of the invention, along the entire length of the internal conductors 125A and 125B along the direction of the current flow therethrough, the first and second aspect ratios of the section orthogonal to the direction of the current flow are greater than one.

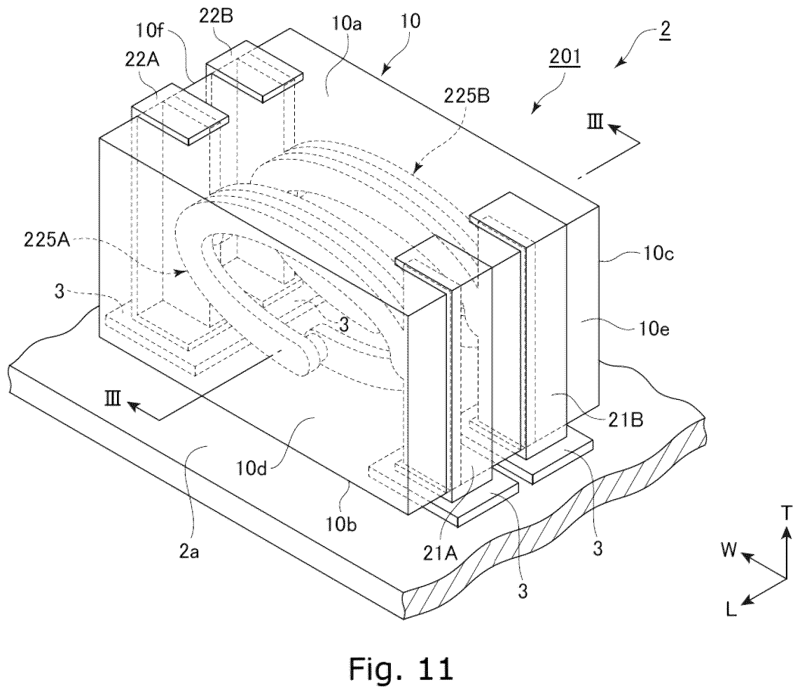

An inductor array 201 according to one or more embodiments of the invention will now be described with reference to FIGS. 11 to 13. The inductor array 201 shown in FIGS. 11 to 13 is different from the inductor array 1 in that it includes, instead of the internal conductors 25A and 25B, internal conductors 225A and 225B. The following description does not mention the similarities between the inductor arrays 201 and 1.

In the embodiment illustrated, the internal conductor 225A includes a winding portion 226A, a lead-out conductor 227A1 and a lead-out conductor 227A2. The winding portion 226A extends in a circumferential direction around a coil axis Ax extending in the L-axis direction. The winding portion 226A is connected at one of the ends thereof to the lead-out conductor 227A1 and at the other end thereof to the lead-out conductor 227A2. The lead-out conductor 227A1 extends along the first side surface 10e from the bottom end thereof to the top end thereof. The lead-out conductor 227A2 extends along the second side surface 10f from the bottom end thereof to the top end thereof. The lead-out conductor 227A1 is connected to the external electrode 21A, and the lead-out conductor 227A2 is connected to the external electrode 22A. In the illustrated embodiment, the winding portion 226A has an elliptic shape when seen in the L-axis direction.

In the embodiment illustrated, the internal conductor 225B includes a winding portion 226B, a lead-out conductor 227B1 and a lead-out conductor 227B2. The winding portion 226B extends in a circumferential direction around the coil axis Ax. The winding portion 226B is connected at one of the ends thereof to the lead-out conductor 227B1 and at the other end thereof to the lead-out conductor 227B2. The lead-out conductor 227B1 extends along the first side surface 10e from the bottom end thereof to the top end thereof. The lead-out conductor 227B2 extends along the second side surface 10f from the bottom end thereof to the top end thereof. The lead-out conductor 227B1 is connected to the external electrode 21B, and the lead-out conductor 227B2 is connected to the external electrode 22B. In the illustrated embodiment, the winding portion 226B has an elliptic shape when seen in the L-axis direction.

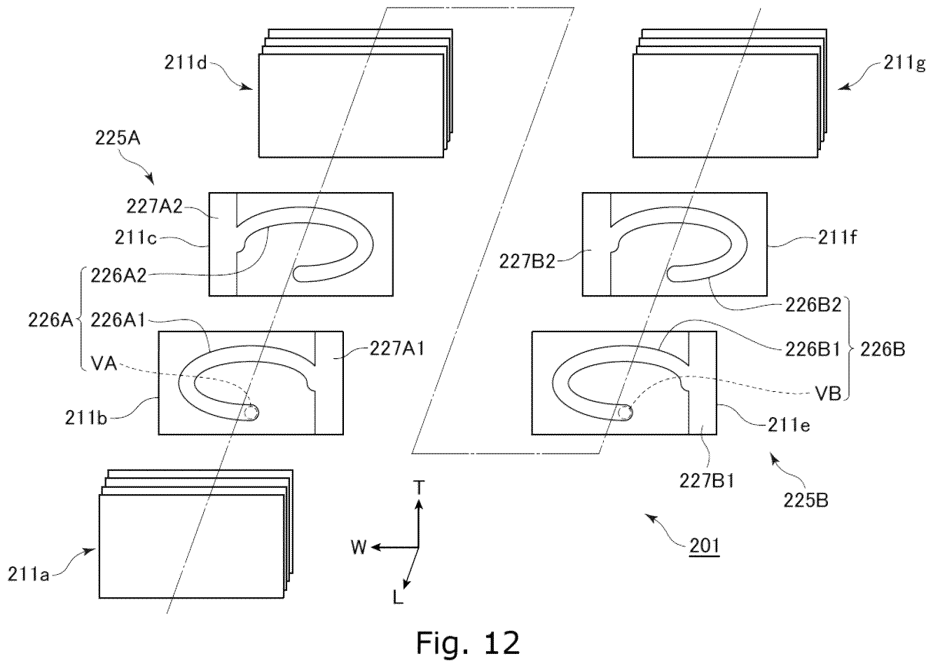

As shown in FIG. 12, the inductor array 201 may have a laminated structure having a plurality of magnetic layers stacked on each other. In FIG. 12, the external electrodes 21A, 22A, 21B and 22B are not shown for convenience of description. In the embodiment shown, the base body 10 includes magnetic layers 211a to 211g. Each of the magnetic layers 211a to 211g is made of a magnetic material. The base body 10 includes the magnetic layer 211a, the magnetic layer 211b, the magnetic layer 211c, the magnetic layer 211d, the magnetic layer 211e, the magnetic layer 211f, and the magnetic layer 211g, which are stacked together in the stated order from the negative side to the positive side in the L-axis direction. As shown, the magnetic layers 211a, 211d and 211g may each include a plurality of magnetic layers. Likewise, the magnetic layers other than the magnetic layers 211a, 211d and 211g may each include a plurality of magnetic layers. The magnetic layers 211a and 211g sandwich the internal conductors 225A and 225B in the L-axis direction so as to cover the internal conductors 225A and 225B on both sides, and thus these magnetic layers may be referred to as the cover layers.

The magnetic layers 211b, 211c, 211e and 211f have, on one of the surfaces thereof, a conductor pattern constituting the internal conductors 225A and 225B. More specifically, a winding pattern 226A1 and the lead-out conductor 227A1 are provided on one of the surfaces of the magnetic layer 211b intersecting the L axis, or the positive-side surface in the L-axis direction, and a winding pattern 226A2 and the lead-out conductor 227A2 are provided on one of the surfaces of the magnetic layer 211c intersecting the L axis, or the positive-side surface in the L-axis direction. Likewise, a winding pattern 226B1 and the lead-out conductor 227B1 are provided on one of the surfaces of the magnetic layer 11e intersecting the L axis, or the positive-side surface in the L-axis direction, and a winding pattern 226B2 and the lead-out conductor 227B2 are provided on one of the surfaces of the magnetic layer 11f intersecting the L axis, or the positive-side surface in the L-axis direction. The winding patterns 226A1, 226A2, 226B1 and 226B2 and the lead-out conductors 227A1, 227A2, 227B1 and 227B2 are formed by, for example, applying onto the magnetic layers a conductive paste made of a metal or alloy having excellent electrical conductivity by screen printing. The electrically conductive material contained in the conductive paste may be Ag, Cu, or alloys thereof. The winding patterns 226A1, 226A2, 226B1 and 226B2 and the lead-out conductors 227A1, 227A2, 227B1 and 227B2 may be made of other materials and formed using other methods. The winding patterns 226A1, 226A2, 226B1 and 226B2 and the lead-out conductors 227A1, 227A2, 227B1 and 227B2 may be formed by, for example, sputtering, ink-jetting, or any other known methods.

The magnetic layers 211b and 211e respectively have vias VA and VB formed therein at a predetermined position. The vias VA and VB are formed by forming a through-hole in the magnetic layers 211b and 211e at the predetermined position so as to extend through the magnetic layers 211b and 211e in the L axis direction and filling the through-holes with a conductive paste.

The winding patterns 226A1 and 226A2 are connected together through the via VA. The winding portion 226A is constituted by these winding patterns 226A1 and 226A2 and the via VA. The winding patterns 226B1 and 226B2 are connected together through the via VB. The winding portion 226B is constituted by these winding patterns 226B1 and 226B2 and the via VB.

In one or more embodiments of the present invention, the winding portion 226A is wound around the coil axis Ax1 a predetermined number of turns. The winding portion 226A may be wound 1.5 turns or less. In the embodiment shown, the winding pattern 226A1 extends approximately 0.75 turns) (270° around the coil axis Ax from its connection with the lead-out conductor 227A1 to its connection with the via VA, and the winding pattern 226A2 extends approximately 0.75 turns) (270° around the coil axis Ax from its connection with the via VA to its connection with the lead-out conductor 227A2. In this manner, the winding portion 226A is wound around the coil axis Ax approximately 1.5 turns) (540°. As mentioned above, the inductor array 201 may be an inductor used in a DC-to-DC converter. As the speed of switching increases for DC-to-DC converters, the inductor used in the DC-to-DC converters is required to have low inductance. Since the winding portion 226A is wound 1.5 turns or less, the inductor including the winding portion 226A can achieve reduced inductance.

In one or more embodiments of the present invention, the winding portion 226B may be shaped in the same manner as the winding portion 226A. More specifically, the shape of the winding portion 226A when seen in the direction of the coil axis Ax may be the same as the shape of the winding portion 226B when seen in the direction of the coil axis Ax. In this manner, the inductor including the winding portion 226A can have the same electrical and magnetic characteristics as the inductor including the winding portion 226B. Since the winding portions 226A and 226B have the same shape, the inductor including the winding portion 226A and the inductor including the winding portion 226B can behave in the same manner responding to external factors (for example, electromagnetic influence made by external devices). Specifically, the winding portion 226B is wound around the coil axis Ax a predetermined number of turns. The winding portion 226B may be wound 1.5 turns or less. In the embodiment shown, the winding pattern 226B1 extends approximately 0.75 turns) (270° around the coil axis Ax from its connection with the lead-out conductor 227B1 to its connection with the via VB, and the winding pattern 226B2 extends approximately 0.75 turns) (270° around the coil axis Ax from its connection with the via VB to its connection with the lead-out conductor 227B2. In this manner, the winding portion 226B is wound around the coil axis Ax approximately 1.5 turns) (540°).

When the winding portions 226A and 226B are shaped like an ellipse when seen in the L-axis direction, the coil axis Ax passes through the middle point of the line segment connecting together the two focal points of the ellipse (the intersection of the major and minor axes of the ellipse).

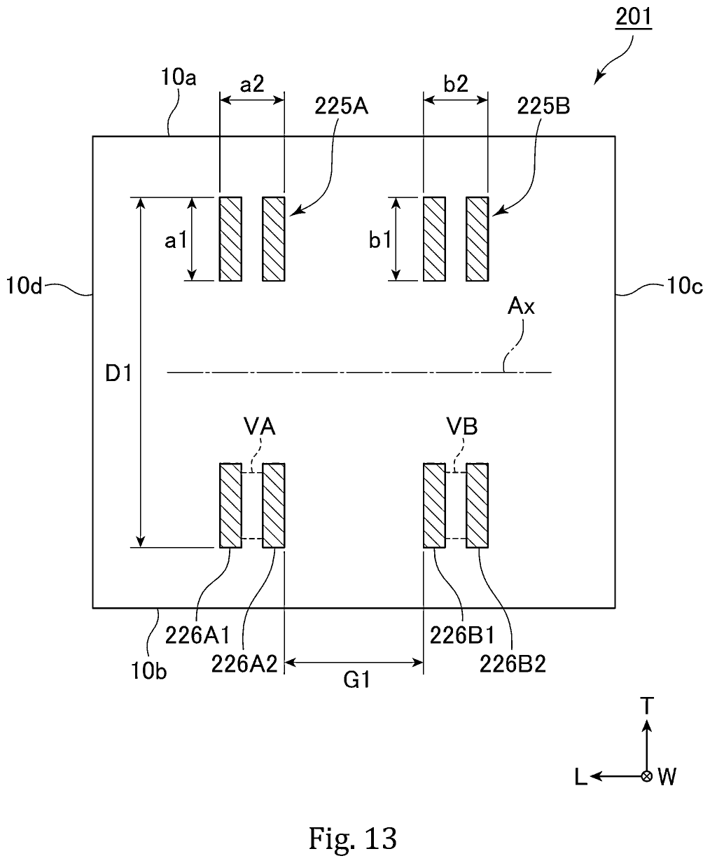

Next, a description is given of the internal conductors 225A and 225B with further reference to FIG. 13. FIG. 13 is a sectional view schematically showing the section of the inductor array 201 along the line III-III, or the section obtained by cutting the inductor array 201 along a plane passing through the coil axis Ax and perpendicular to the second principal surface 10b. When the winding portions 226A and 226B are shaped like an ellipse when seen in the L-axis direction, the current flows through the internal conductors 225A and 225B in the W-axis direction (perpendicularly to the plane of the paper) in the section shown in FIG. 13. This means that the section of the internal conductors 225A and 225B shown in FIG. 13 is an example section obtained by cutting the internal conductors 225A and 225B along a plane orthogonal to the current flowing direction through the internal conductors 225A and 225B.

The first aspect ratio of the internal conductor 225A is defined in the same manner as the first aspect ratio of the internal conductor 25A, and the second aspect ratio of the internal conductor 225B is defined in the same manner as the second aspect ratio of the internal conductor 25B. More specifically, when a1 and a2 respectively refer to the dimension in the direction perpendicular to the L-axis direction and the dimension in the L-axis direction of the section of the internal conductor 225A obtained by cutting the internal conductor 225A along a plane orthogonal to the direction of the electric current flow through the internal conductor 225A, the ratio of a1 to a2 (a1/a2) may be referred to as a first aspect ratio for the internal conductor 225A. When b1 and b2 respectively refer to the dimension in the direction perpendicular to the L-axis direction and the dimension in the L-axis direction of the section of the internal conductor 225B obtained by cutting the internal conductor 225B along a plane orthogonal to the direction of the electric current flow through the internal conductor 225B, the ratio of b1 to b2 (b1/b2) may be referred to as a second aspect ratio of the internal conductor 225B. As shown in FIG. 13, when the internal conductor 225A or 225B has winding patterns in two or more layers, the dimension a2 of the section of the internal conductor 225A in the L-axis direction or the dimension b2 of the section of the internal conductor 225B in the L-axis direction indicates the spacing between (i) one of the outermost ends of the winding patterns in the L-axis direction and (ii) the other of the outermost ends of the winding patterns in the L-axis direction. In the embodiment shown, the internal conductor 225A has the winding patterns 226A1 and 226A2, and the spacing between (i) the positive-side one of the ends in the L-axis direction of the winding pattern 226A1 and (ii) the negative-side one of the ends in the L-axis direction of the winding pattern 226A2 thus represents the dimension a2 in the L-axis direction of the section of the internal conductor 225A. Likewise, the internal conductor 225B has the winding patterns 226B1 and 226B2, and the spacing between (i) the positive-side one of the ends in the L-axis direction of the winding pattern 226B1 and (ii) the negative-side one of the ends in the L-axis direction of the winding pattern 226B2 thus represents the dimension b2 in the L-axis direction of the section of the internal conductor 225B. In one or more embodiments of the invention, the first aspect ratio of the internal conductor 225A is greater than one. In one or more embodiments of the invention, the second aspect ratio of the internal conductor 225B is greater than one.

In one or more embodiments of the present invention, not only for the section of the internal conductors 225A and 225B along a plane passing thorough the coil axis Ax and perpendicular to the second principal surface 10b, shown in FIG. 13, but also for any section of the internal conductor 225A orthogonal to the direction of the current flow through the internal conductor 225A, the first aspect ratio is greater than one, and, for any section of the internal conductor 225B orthogonal to the direction of the current flow through the internal conductor 225B, the second aspect ratio is greater than one. In one or more embodiments of the invention, along the entire length of the internal conductors 225A and 225B along the direction of the current flow therethrough, the first and second aspect ratios of the section orthogonal to the direction of the current flow are greater than one.

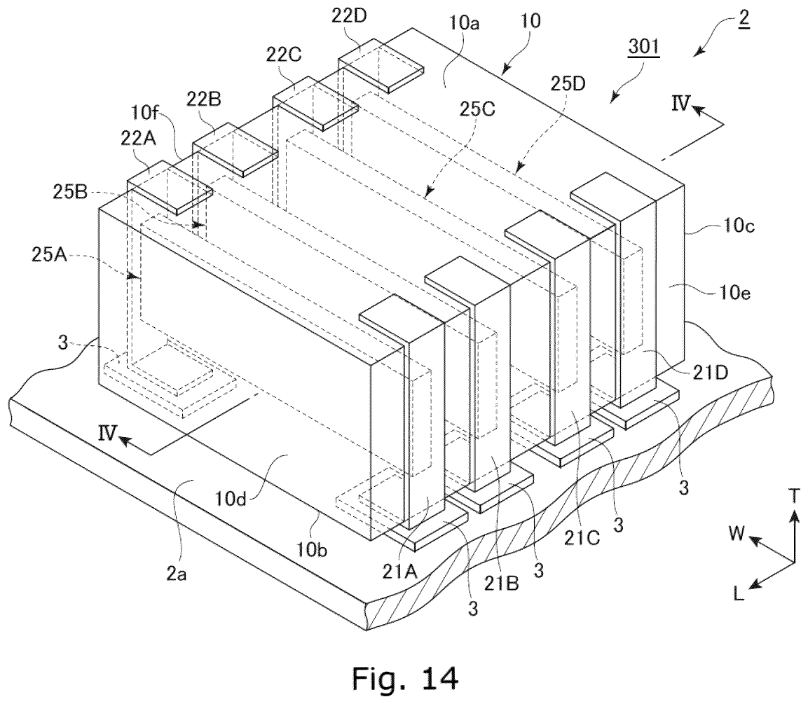

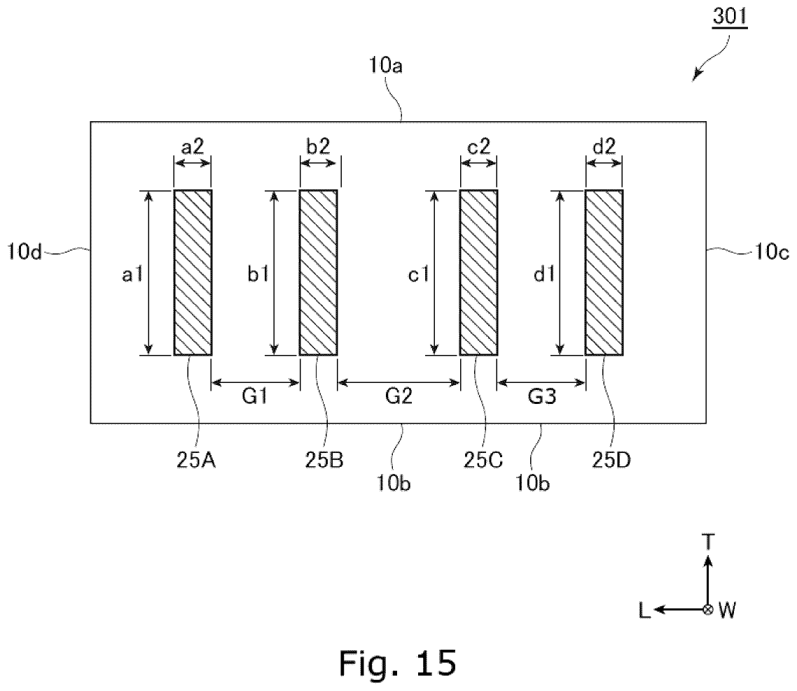

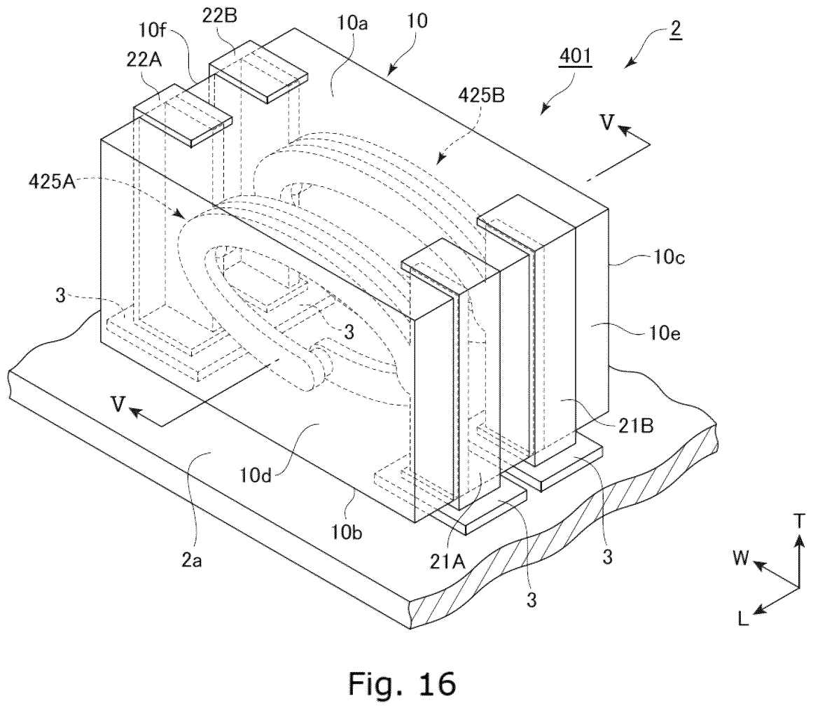

Subsequently, an inductor array 301 according to one or more embodiments of the present invention will be described with reference to FIGS. 14 and 15. The inductor array 301 is different from the inductor array 1 including two internal conductors and two sets of external electrodes in that the inductor array 301 includes four internal conductors and four sets of external electrodes. The following description does not mention the similarities between the inductor arrays 301 and 1.

The inductor array 301 includes internal conductors 25A, 25B, 25C and 25D disposed in the base body 10 and external electrodes 21A, 21B, 21C, 21D, 22A, 22B, 22C and 22D disposed on the surface of the base body 10. The internal conductors 25A and 25B are configured and disposed in the same manner as the internal conductors 25A and 25B in the inductor array 1. The internal conductor 25C is coupled to the external electrode 21C at one end thereof and to the external electrode 22C at the other end thereof. The internal conductor 25D is coupled to the external electrode 21D at one end thereof and to the external electrode 22D at the other end thereof. Thus, the inductor array 301 includes a first inductor including the internal conductor 25A and the external electrodes 21A and 22A, a second inductor including the internal conductor 25B and the external electrodes 21B and 22B, a third inductor including the internal conductor 25C and the external electrodes 21C and 22C, and a fourth inductor including the internal conductor 25D and the external electrodes 21D and 22D. The eight external electrodes 21A to 21D and 22A to 22D of the inductor array 301 are arranged such that they respectively face the corresponding lands 3 when the inductor array 301 is mounted on the mounting substrate 2a.

In the illustrated embodiment, the internal conductor 25C is disposed on the opposite side to the internal conductor 25A with respect to the internal conductor 25B in the L-axis direction. The internal conductor 25D is disposed on the opposite side to the internal conductor 25B with respect to the internal conductor 25C in the L-axis direction. The internal conductors 25A, 25B, 25C, and 25D are arranged in this order from the positive side to the negative side in the L-axis direction. The internal conductor 25A faces the second end surface 10d of the base body 10 on one side of the direction along a first coil axis Ax1 (positive side of the L-axis direction). In other words, there are no internal conductors between the internal conductor 25A and the second end surface 10d. The internal conductor 25D faces the first end surface 10c of the base body 10 on one side of the direction along a fourth coil axis Ax4 (negative side of the L-axis direction). In other words, there are no internal conductors between the internal conductor 25D and the first end surface 10c. The internal conductors 25B and 25C are disposed between the internal conductors 25A and 25D.

As described above, the internal conductor 25B is disposed at a distance G1 from the internal conductor 25A in the L-axis direction. The internal conductor 25C is disposed at a distance G2 from the internal conductor 25B in the L-axis direction. The internal conductor 25D is disposed at a distance G3 from the internal conductor 25C in the L-axis direction. In one or more embodiments of the invention, the spacing G2 between the internal conductors 25B and 25C is greater than the spacing G1 between the internal conductors 25A and 25B. In one or more embodiments of the invention, the spacing G2 between the internal conductors 25B and 25C is greater than the spacing G3 between the internal conductors 25C and 25D. The spacings G1 and G3 may be equal to or different from each other. The spacing G2 between the internal conductors 25B and 25C may be 0.3 mm or less. The shapes of the internal conductors 25A, 25B, 25C, and 25D viewed from the L-axis direction may be the same as each other. Since the internal conductors 25A, 25B, 25C, and 25D have the same shape, the inductor array 301 can easily achieve uniform electrical characteristics among the lines formed therein.

In the illustrated embodiment, the internal conductor 25C has a rectangular parallelepiped shape. Thus, when a voltage is applied between the external electrode 21C and the external electrode 22C, the current flows through the internal conductor 25C along the W axis. In the illustrated embodiment, the internal conductor 25D has a rectangular parallelepiped shape. Thus, when a voltage is applied between the external electrode 21D and the external electrode 22D, the current flows through the internal conductor 25D along the W axis. The internal conductors 25C and 25D may have a rounded section similarly to the internal conductors 25A and 25B (see FIG. 6).

Referring to FIG. 15, the aspect ratios of the internal conductors 25C and 25D will be described. FIG. 15 is a sectional view of the inductor array 301 along the line IV-IV, schematically showing sections of the internal conductors 25A, 25B, 25C, and 25D cut along a plane perpendicular to the W-axis direction. Since the current flows in the W-axis direction through each of the internal conductors 25A, 25B, 25C, and 25D as described above, FIG. 15 illustrates example sections of the internal conductors 25A, 25B, 25C, and 25D cut along the plane orthogonal to the direction of current flowing through the internal conductors 25A, 25B, 25C, and 25D.

As shown in FIG. 15, the section of the internal conductor 25C cut along the plane perpendicular to the direction of the current flowing through the internal conductor 25C has a dimension c2 in a reference direction and a dimension c1 in a direction perpendicular to the reference direction. In the illustrated embodiment, the reference direction coincides with the L-axis direction, and the direction perpendicular to the reference direction of the section of the internal conductor 25C cut along the plane perpendicular to the current flowing direction coincides with the T-axis direction. The ratio of c1 to c2 (c1/c2) is herein defined as a third aspect ratio. In one or more embodiments of the invention, the third aspect ratio of the internal conductor 25C is greater than one (1). Similarly, the section of the internal conductor 25D cut along a plane perpendicular to the direction of the current flowing through the internal conductor 25D has a dimension d2 in a reference direction and a dimension d1 in a direction perpendicular to the reference direction. In the illustrated embodiment, the reference direction coincides with the L-axis direction, and the direction perpendicular to the reference direction of the section of the internal conductor 25D cut along the plane perpendicular to the current flowing direction coincides with the T-axis direction. The ratio of d1 to d2 (d1/d2) is herein defined as a fourth aspect ratio. In one or more embodiments of the invention, the fourth aspect ratio of the internal conductor 25D is greater than one (1).

In one or more embodiments of the invention, not only for the sections of the internal conductors 25C and 25D cut along the plane that is parallel to the LT plane and passes the center of the base body 10 as illustrated in FIG. 15, but also for any section of the internal conductor 25C orthogonal to the direction of the current flowing through the internal conductor 25C, the third aspect ratio is greater than one, and, for any section of the internal conductor 25D orthogonal to the direction of the current flowing through the internal conductor 25D, the fourth aspect ratio is greater than one. In one or more embodiments of the invention, for the entire length of the internal conductors 25C and 25D along the direction of the current flowing through the internal conductors 25C and 25D, the section orthogonal to the current flowing direction has a third or fourth aspect ratio of greater than one.

The inductor array 301 may include three inductors, or five or more inductors. The aspect ratio of each internal conductor provided in the inductor array 301 is defined in the same way as the first aspect ratio of the internal conductor 25A. The aspect ratio of each internal conductor provided in the inductor array 301 is greater than one.

Next, a description is given of an example method of manufacturing the inductor array 1 according to one embodiment of the present invention. FIG. 2 will be referred to as necessary to describe the manufacturing method. In one or more embodiments of the invention, the inductor array 1 is produced by a sheet lamination method in which magnetic sheets are stacked together. The first step of the sheet lamination method for producing the inductor array 1 is to prepare the magnetic sheets. The magnetic sheets are formed, for example, from a slurry obtained by mixing and kneading metal magnetic particles made of a soft magnetic material with a resin. The slurry is molded into the magnetic sheets using a sheet molding machine such as a doctor blade sheet molding machine. The resin mixed and kneaded together with the metal magnetic particles may be, for example, a polyvinyl butyral (PVB) resin, an epoxy resin, or any other resin materials having an excellent insulation property.

The magnetic sheets are cut in a predetermined shape. Next, a conductive paste is applied to the magnetic sheets cut into a predetermined shape by a known method such as screen printing, thereby forming a plurality of unfired conductor patterns that will later form the internal conductors 25A and 25B after firing. The conductive paste is made by mixing and kneading, for example, Ag, Cu, or alloys thereof and a resin.

In the way described above, the magnetic sheets having the unfired conductor patterns formed thereon and the unfired vias formed therein are prepared, and a mother laminate is prepared by stacking together these magnetic sheets and magnetic sheets having no conductors therein or thereon. The magnetic sheets having no conductors formed therein or thereon can contribute to adjust the spacing between the internal conductors 25A and 25B.

Next, the mother laminate is diced using a cutter such as a dicing machine or a laser processing machine to obtain a chip laminate.

Next, the chip laminate is subjected to heat treatment at a temperature of 600° C. to 850° C. for a duration of 20 to 120 minutes. This heat treatment degreases the chip laminate and fires the magnetic sheets and the conductor paste, thereby providing the base body 10 that includes the internal conductors 25A and 25B thereinside. If the magnetic sheets contain a thermosetting resin, the thermosetting resin may be cured by performing heat treatment at a lower temperature onto the chip laminate. This cured resin serves as a binder that binds the metal magnetic particles contained in the magnetic sheets together. The heat treatment at a lower temperature is performed at a temperature of 100° C. to 200° C. for a duration of approximately 20 to 120 minutes, for example.

Following the heat treatment, a conductive paste is applied to the surface of the heat-treated chip laminate (that is, the base body 10) to form the external electrodes 21A, 22A, 21B and 22B. Through the above-described process, the inductor array 1 is obtained. The inductor arrays 101, 201 and 301 can be made using the same manufacturing method as the inductor array 1.

The above-described manufacturing method can be modified by omitting some of the steps, adding steps not explicitly described, and/or reordering the steps. Such omission, addition, or reordering is also included in the scope of the present invention unless diverged from the purport of the present invention.

The inductor array 1 can be made in different manners than the method described above. The inductor array 1 may be produced by a lamination method other than the sheet lamination method (e.g., the printing lamination method), the thin film process, the compression molding process, or other known methods.

Next, advantageous effects of the foregoing embodiments will be described. According to one or more embodiments of the invention, the internal conductor 25A is configured in the base body 10 such that it is connected at one end thereof to the external electrode 21A and connected at the other end thereof to the external electrode 22A. When the inductor array 1 is in use, an electric current flows through the internal conductor 25A. When the section of the internal conductor 25A cut along the plane perpendicular to the direction of the current flowing therein has the dimension a2 in the L-axis direction and the dimension a1 in the direction perpendicular to the L-axis direction, the first aspect ratio, which is the ratio of the dimension a1 to the dimension a2 (a1/a2), is greater than one. Thus the magnetic flux generated when the current flowing through the internal conductor 25A changes is more likely to be oriented in the direction orthogonal to the L-axis direction than in the L-axis direction. This makes it more difficult for the magnetic flux generated around the internal conductor 25A to reach the internal conductor 25B, which is disposed spaced away from the internal conductor 25A in the L-axis direction. When the section of the internal conductor 25B cut along the plane perpendicular to the direction of the current flowing therein has the dimension b2 in the L-axis direction and the dimension b1 in the direction perpendicular to the L-axis direction, the second aspect ratio, which is the ratio of the dimension b1 to the dimension b2 (b1/b2), is greater than one. Thus the magnetic flux generated when the current flowing through the internal conductor 25B changes is more likely to be oriented in the direction orthogonal to the L-axis direction than in the L-axis direction. This makes it more difficult for the magnetic flux generated around the internal conductor 25B to reach the internal conductor 25A, which is disposed spaced away from the internal conductor 25B in the L-axis direction, when compared with a case where the second aspect ratio of the internal conductor is 1 or less. As a result of the above, the magnetic coupling between the internal conductor 25A and the internal conductor 25B can be lessened in the inductor array 1. The inductor arrays 101, 201 and 301 can produce the same advantageous effects.

In one or more embodiments of the present invention, the base body 10 is configured with a relative magnetic permeability of 100 or less in order to achieve low inductance. When the base body 10 has a relative magnetic permeability of 100 or less, there are difficulties in keeping the magnetic flux generated by the internal conductor 25A in the vicinity of the internal conductor 25A and in keeping the magnetic flux generated by the internal conductor 25B in the vicinity of the internal conductor 25B. For this reason, reducing the distance G1 between the internal conductors 25A and 25B is likely to increase the magnetic coupling between the internal conductors 25A and 25B. In one or more embodiments of the present invention, the internal conductors 25A and 25B are configured such that the first and second aspect ratios are greater than one as described above. Accordingly, irrespective of a short distance G1 (for example, 0.3 mm or less) in the L-axis direction between the internal conductors 25A and 25B, only weak magnetic coupling can be obtained between the internal conductors 25A and 25B. Therefore, the inductor array 1 can achieve a small size in the L-axis direction. The inductor arrays 101, 201 and 301 can produce the same advantageous effects.

As noted, one or more embodiments of the present invention can accomplish size reduction in the L-axis direction, so that the inductor array 1, 101, 201, 301 can have lessened magnetic coupling between the inductors.

In one or more embodiments of the present invention, the base body 10 may be configured such that its relative magnetic permeability is within the range of 30 to 100 throughout the entire region. If the base body 10 includes a region where the relative magnetic permeability is less than 30, the region may substantially serve as a magnetic gap. If the base body 10 includes a low-permeability region that may serve as a magnetic gap, the magnetic flux generated by one of the internal conductors 25A and 25B may avoid following a magnetic path extending through the low-permeability region and be thus likely to interfere with the other internal conductor. Furthermore, if the base body 10 includes a low-permeability region that may serve as a magnetic gap, this may result in magnetic flux leakage and increase magnetic interference with devices other than the inductor array 1, 101, 201 and 301. Having a relative magnetic permeability in a range of 30 to 100 throughout the entire region, the base body 10 includes no region serving as a magnetic gap. With such a design, magnetic coupling can be lessened between the internal conductors included in the inductor array 1, 101, 201, 301, and magnetic interference can be prevented from affecting devices other than the inductor array 1, 101, 201, 301.

In one or more embodiments of the invention, the third aspect ratio of the internal conductor 25C may be greater than one (1). With such a design, the magnetic coupling between the internal conductor 25C and other adjacent internal conductors in the L-axis direction (e.g., the internal conductors 25B and 25D) can be lessened. In one or more embodiments of the invention, the fourth aspect ratio of the internal conductor 25D may be greater than one (1). With such a design, the magnetic coupling between the internal conductor 25D and other adjacent internal conductors in the L-axis direction (e.g., the internal conductor 25C) can be lessened.

In one or more embodiments of the present invention, the internal conductor 25A has a rounded section. This design allows the magnetic flux generated by the internal conductor 25A to be more likely to follow a path closer to the center of the section of the internal conductor 25A. Accordingly, the magnetic flux generated by the internal conductor 25A is less likely to reach other internal conductors (for example, the internal conductor 25B). As a consequence, the magnetic coupling between the internal conductor 25A and other internal conductors can be lessened. In one or more embodiments of the present invention, an internal conductor other than the internal conductor 25A may have a rounded section. This can reduce magnetic coupling between the internal conductor and the other internal conductors.

In the inductor array 301 according to one or more embodiments of the present invention, the internal conductor 25B and the internal conductor 25C are disposed between the internal conductor 25A and the internal conductor 25D in the L-axis direction. Therefore, the magnetic flux generated from the internal conductor 25B and the magnetic flux generated from the internal conductor 25C are less likely to leak outside the base body 10 compared to the magnetic flux generated from the internal conductors 25A and 25D. Whereas the magnetic flux generated from the internal conductor 25A is likely to leak outside the base body 10 since the internal conductor 25A faces the second end surface 10d of the base body 10 in the L-axis direction. Similarly the magnetic flux generated from the internal conductor 25D is likely to leak outside the base body 10 since the internal conductor 25D faces the first end surface 10c of the base body 10 in the L-axis direction. The above arrangement is likely to result in the magnetic coupling between the internal conductors 25B and 25C being stronger than the magnetic coupling between the internal conductors 25A and 25B and the magnetic coupling between the internal conductors 25C and 25D. According to one or more embodiments of the present invention, the spacing G2 between the internal conductors 25B and 25C is greater than the spacing G1 between the internal conductors 25A and 25B. This lessens the magnetic coupling between the internal conductors 25B and 25C, thereby reducing the strength of the magnetic coupling between the internal conductors 25B and 25C to reach a similar level as the strength of the magnetic coupling between the internal conductors 25A and 25B. Likewise, the spacing G2 between the internal conductors 25B and 25C is greater than the spacing G3 between the internal conductors 25C and 25D. This lessens the magnetic coupling between the internal conductors 25B and 25C, thereby reducing the strength of the magnetic coupling between the internal conductors 25B and 25C to reach a similar level as the strength of the magnetic coupling between the internal conductors 25C and 25D.

In one or more embodiments of the invention, when the internal conductor 25A and the internal conductor 25B are spaced apart in the L-axis direction, the shape of the internal conductor 25A viewed from the L-axis direction is identical to the shape of the internal conductor 25B, so that the inductor including the internal conductor 25A and the inductor including the internal conductor 25B will behave similarly in response to external factors (e.g., electromagnetic influence from external elements). The same effect is achieved when the shape of the internal conductor 125A viewed from the L-axis direction is the same as the shape of the internal conductor 125B, and when the shape of the internal conductor 225A (e.g., the shape of the winding portion 226A) viewed from the L-axis direction is the same as the shape of the internal conductor 225B (e.g., the shape of the winding portion 226B). When the shapes of the internal conductors 25A, 25B, 25C, and 25D viewed from the L-axis direction are identical to each other, the four inductors that include these internal conductors can be configured to exhibit similar behavior to external factors.

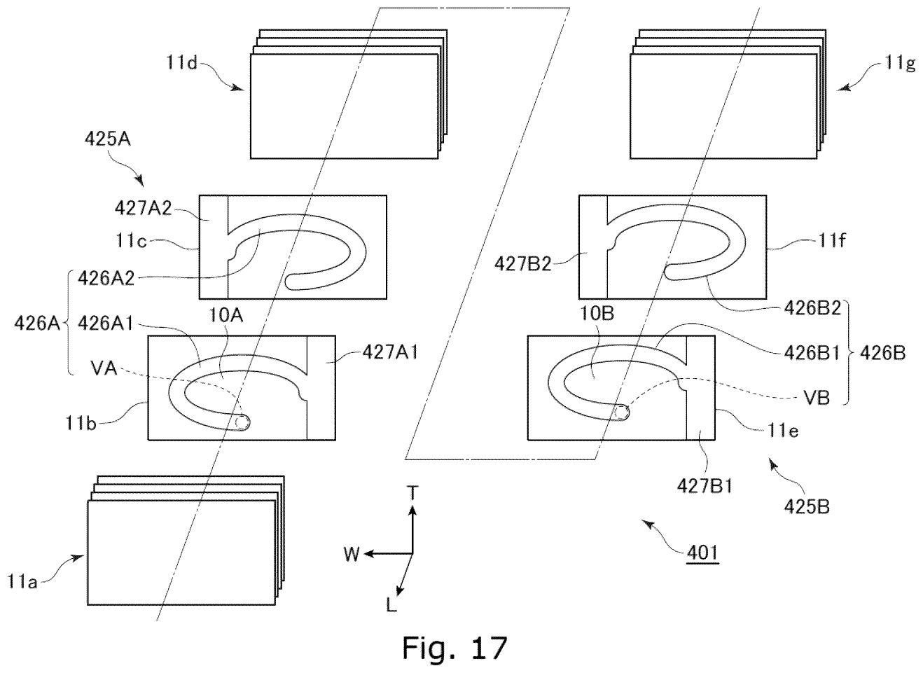

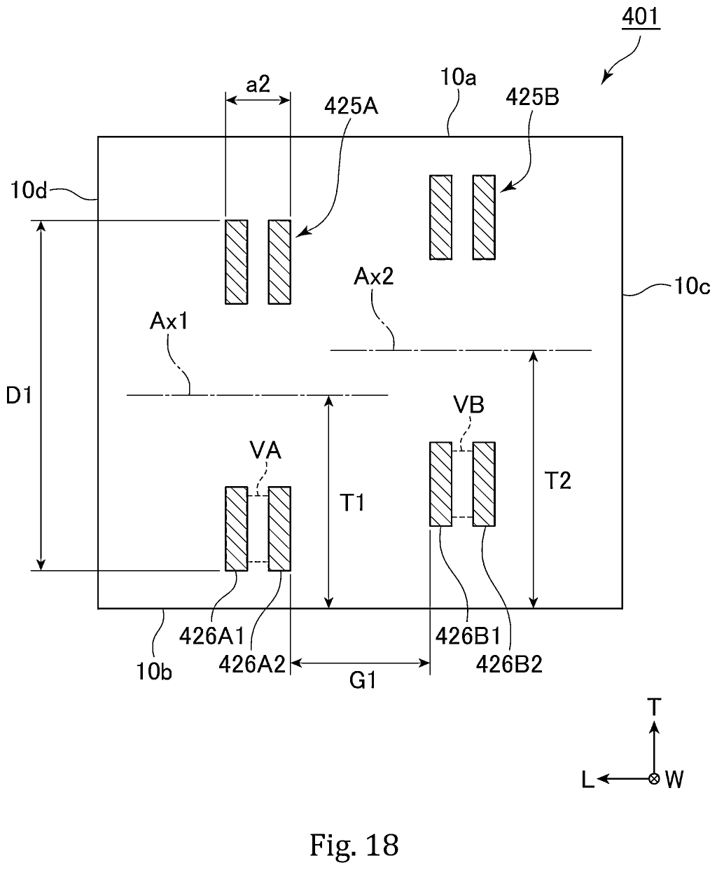

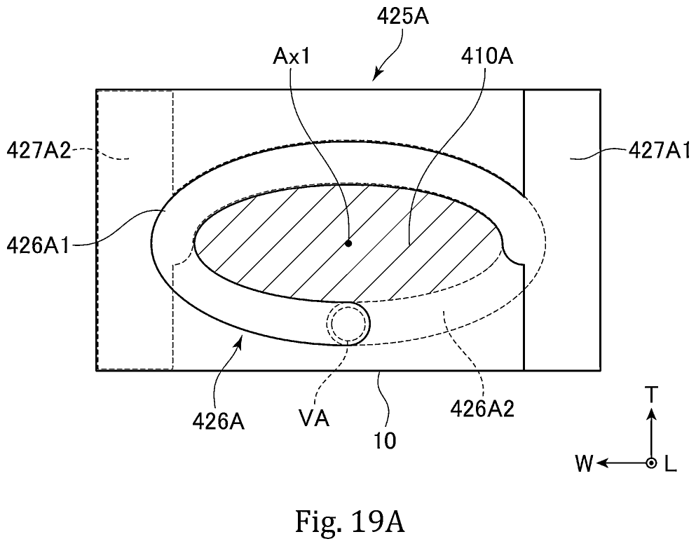

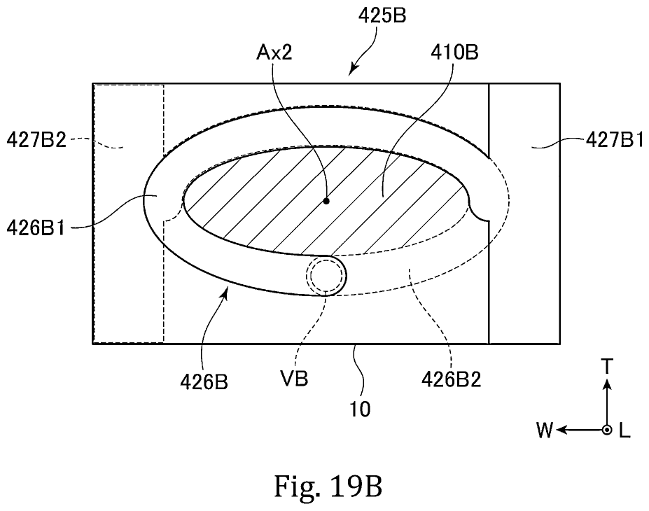

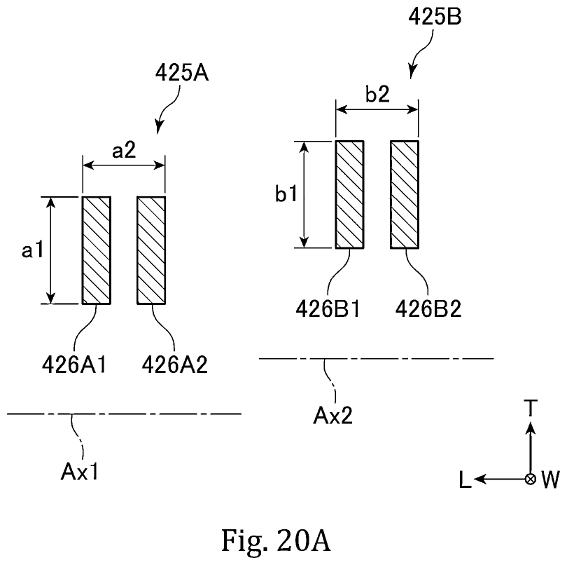

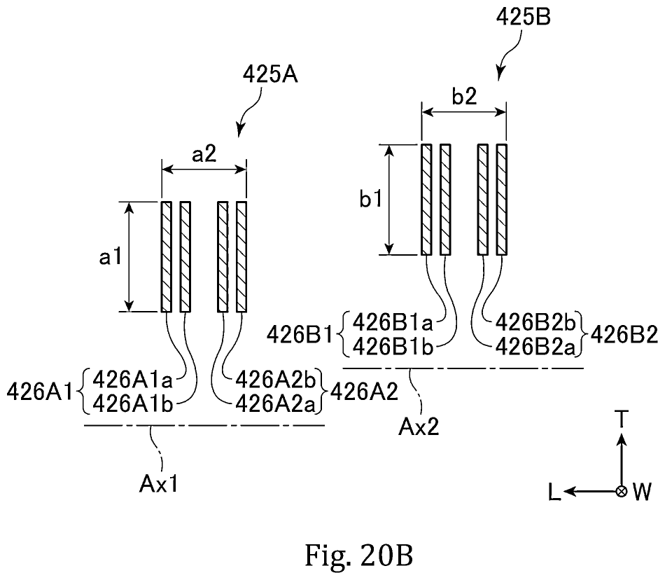

The following describes an inductor array 401 according to one or more embodiments of the present invention with reference to FIGS. 16 to 20A. FIG. 16 is a perspective view of the inductor array 401 relating to one embodiment of the present invention, FIG. 17 is an exploded view of the inductor array 401, FIG. 18 schematically shows a section of the inductor array 401 observed when cut along the line V-V, FIGS. 19A and 19B shows internal conductors in the inductor array 401 with making a part thereof transparent, and FIG. 20A schematically shows in section winding patterns constituting winding portions of the internal conductors included in the inductor array 401.

As shown, the inductor array 401 includes a base body 10, internal conductors 425A and 425B disposed in the base body 10, and external electrodes 21A, 21B, 22A and 22B disposed on the surface of the base body 10. The internal conductor 425A is connected at one end thereof to the external electrode 21A and connected at the other end thereof to the external electrode 22A. The internal conductor 425B is connected at one end thereof to the external electrode 21B and connected at the other end thereof to the external electrode 22B. As noted, the inductor array 1 includes a first inductor having the internal conductor 425A and external electrodes 21A and 22A and a second inductor having the internal conductor 425B and external electrodes 21B and 22B. The external electrodes 21A, 22A, 21B and 22B are spaced away from each other.

The inductor array 401 is used in, for example, a large-current circuit through which a large electric current flows. The inductor array 401 may be mounted on a mounting board 2a. Since the first inductor having the internal conductor 425A and external electrodes 21A and 22A and the second inductor having the internal conductor 425B and external electrodes 21B and 22B are packaged within a single chip, the inductor array 401 is particularly suitably used in small-sized electronic devices, which require their electronic components be highly densely mounted.

The top-bottom direction of the inductor array 401 refers to the top-bottom direction in FIG. 16. The thickness direction of the inductor array 401 or the base body 10 may be the direction perpendicular to at least one of the top surface 10a or the mounting surface 10b. The length direction of the inductor array 401 or the base body 10 may be the direction perpendicular to at least one of the first end surface 10c or the second end surface 10d. The width direction of the inductor array 401 or the base body 10 may be the direction perpendicular to at least one of the first side surface 10e or the second side surface 10f. The width direction of the inductor array 401 or the base body 10 may be the direction perpendicular to the thickness and length directions of the inductor array 401 or the base body 10.

As described above, the base body 10 of the inductor array 401 has a low relative magnetic permeability of 100 or less. This means that each line of inductor in the inductor array 401 also has low inductance L. As each line of inductor exhibits low inductance, the inductor array 401 is unlikely to experience magnetic saturation. This allows a large current to flow through each line of inductor in the inductor array 401. Accordingly, in one or more embodiments of the present invention, each line of inductor in the inductor array 401 can achieve increased energy density Ed, which is expressed as the product of the inductance L of the inductor and the result of dividing the square of the current I flowing through the inductor by the volume V of the inductor (Ed=L× 12/V). For example, when the inductance L of each line of inductor in the inductor array 401 is less than 100 nH, the inductor can have Ed of 1500 nH·A²/mm³. Alternatively, when the inductance L of each line of inductor in the inductor array 401 is less than 50 nH, the inductor can have Ed of 2000 nH·A²/mm³. When the inductance L of each line of inductor in the inductor array 401 is less than 25 nH, the inductor can have Ed of 2500 nH·A²/mm³.

In the embodiment illustrated, the internal conductor 425A includes a winding portion 426A, a lead-out conductor 427A1 and a lead-out conductor 427A2. The winding portion 426A extends in a circumferential direction around a coil axis Ax1 extending in a direction parallel to the mounting surface 10b of the base body 10. In other words, the winding portion 426A is wound around the coil axis Ax1. The winding portion 426A is connected at one of the ends thereof to the lead-out conductor 427A1 and at the other end thereof to the lead-out conductor 427A2. The lead-out conductor 427A1 extends along the first side surface 10e from the bottom end thereof to the top end thereof. The lead-out conductor 427A2 extends along the second side surface 10f from the bottom end thereof to the top end thereof. The lead-out conductor 427A1 is connected to the external electrode 21A, and the lead-out conductor 427A2 is connected to the external electrode 22A. In the illustrated embodiment, the winding portion 426A has an elliptic shape when seen in the L-axis direction.

In the embodiment illustrated, the internal conductor 425B includes a winding portion 426B, a lead-out conductor 427B1 and a lead-out conductor 427B2. The winding portion 426B extends in a circumferential direction around a coil axis Ax2 extending in a direction parallel to the mounting surface 10b of the base body 10. In other words, the winding portion 426B is wound around the coil axis Ax2. The winding portion 426B is connected at one of the ends thereof to the lead-out conductor 427B1 and at the other end thereof to the lead-out conductor 427B2. The lead-out conductor 427B1 extends along the first side surface 10e from the bottom end thereof to the top end thereof. The lead-out conductor 427B2 extends along the second side surface 10f from the bottom end thereof to the top end thereof. The lead-out conductor 427B1 is connected to the external electrode 21B, and the lead-out conductor 427B2 is connected to the external electrode 22B. In the illustrated embodiment, the winding portion 426B has an elliptic shape when seen in the L-axis direction.

As shown in FIG. 17, the inductor array 401 may have a laminated structure having a plurality of magnetic layers stacked on each other. In FIG. 17, the external electrodes 21A, 22A, 21B and 22B are not shown for convenience of description. In the embodiment shown, the base body 10 includes magnetic layers 11a to 11g. Each of the magnetic layers 11a to 11g is made of a magnetic material. The base body 10 includes the magnetic layer 11a, the magnetic layer 11b, the magnetic layer 11c, the magnetic layer 11d, the magnetic layer 11e, the magnetic layer 11f, and the magnetic layer 11g, which are stacked together in the stated order from the positive side to the negative side in the L-axis direction. As shown, the magnetic layers 11a, 11d and 11g may each include a plurality of magnetic layers. Likewise, the magnetic layers other than the magnetic layers 11a, 11d and 11g may each include a plurality of magnetic layers. The magnetic layers 11a and 11g sandwich the internal conductors 425A and 425B in the L-axis direction so as to cover the internal conductors 425A and 425B on both sides, and thus these magnetic layers may be referred to as the cover layers.

The magnetic layers 11b, 11c, 11e and 11f have, on one of the surfaces thereof, a conductor pattern constituting the internal conductors 425A and 425B. More specifically, the winding pattern 426A1 and lead-out conductor 427A1 are provided on one of the surfaces of the magnetic layer 11b intersecting the L axis, or the positive-side surface in the L-axis direction, and the winding pattern 426A2 and lead-out conductor 427A2 are provided on one of the surfaces of the magnetic layer 11c intersecting the L axis, or the positive-side surface in the L-axis direction. Likewise, the winding pattern 426B1 and lead-out conductor 427B1 are provided on one of the surfaces of the magnetic layer 11e intersecting the L axis, or the positive-side surface in the L-axis direction, and the winding pattern 426B2 and lead-out conductor 427B2 are provided on one of the surfaces of the magnetic layer 11f intersecting the L axis, or the positive-side surface in the L-axis direction. The winding patterns 426A1, 426A2, 426B1 and 426B2 and the lead-out conductors 427A1, 427A2, 427B1 and 427B2 are formed by, for example, applying onto the magnetic layers a conductive paste made of a metal or alloy having excellent electrical conductivity by screen printing. The electrically conductive material contained in the conductive paste may be Ag, Cu, or alloys thereof. The winding patterns 426A1, 426A2, 426B1 and 426B2 and the lead-out conductors 427A1, 427A2, 427B1 and 427B2 may be made of other materials and formed using other methods. The winding patterns 426A1, 426A2, 426B1 and 426B2 and the lead-out conductors 427A1, 427A2, 427B1 and 427B2 may be formed by, for example, sputtering, ink-jetting, or any other known methods.

The magnetic layers 11b and 11e respectively have vias VA and VB formed therein at a predetermined position. The vias VA and VB are formed by forming a through-hole at the respective predetermined position in the magnetic layers 11b and 11e so as to extend through the magnetic layers 11b and 11e in the L axis direction and filling the through-holes with a conductive paste.

The winding patterns 426A1 and 426A2 are connected together through the via VA. The winding portion 426A is constituted by these winding patterns 426A1 and 426A2 and the via VA. The winding patterns 426B1 and 426B2 are connected together through the via VB. The winding portion 426B is constituted by these winding patterns 426B1 and 426B2 and the via VB.

In one or more embodiments of the present invention, the winding portion 426A is wound a predetermined number of turns around the coil axis Ax1. The winding portion 426A may be wound 1.5 turns or less. As shown in FIG. 19A, in the embodiment shown, the winding pattern 426A1 extends approximately 0.75 turns) (270° around the coil axis Ax1 from its connection with the lead-out conductor 427A1 to its connection with the via VA, and the winding pattern 426A2 extends approximately 0.75 turns) (270° around the coil axis Ax1 from its connection with the via VA to its connection with the lead-out conductor 427A2. In this manner, the winding portion 426A is wound around the coil axis Ax1 approximately 1.5 turns) (540°. As described above, the inductor array 401 may be an inductor for use in a DC-to-DC converter. As the speed of switching increases for DC-to-DC converters, the inductor used in the DC-to-DC converters is required to have low inductance. Since the winding portion 426A is wound 1.5 turns or less, the inductor including the winding portion 426A can achieve reduced inductance.

A core region 410A denotes a region of the base body 10 that is enclosed within the winding portion 426A when seen in the L-axis direction. In one embodiment, the coil axis Ax1 passes through the geometric center of the core region 410A when seen in the L-axis direction and extends in the direction parallel to the mounting surface 10b. In a case where the winding portion 426A is shaped like an ellipse when seen in the L-axis direction as shown in FIG. 19A, the geometric center of the core region 410A is the middle point of the line segment connecting together the two focal points of the ellipse (the intersection of the major and minor axes of the ellipse). When seen in the L-axis direction, the shape of the winding portion 426A is not limited to an ellipse. The winding portion 426A may be shaped like an oval, a circle, a rectangle, a polygon other than a rectangle and other various shapes.

In one or more embodiments of the present invention, the winding portion 426B may be shaped in the same manner as the winding portion 426A. More specifically, the shape of the winding portion 426A when seen in the direction of the coil axis Ax1 may be the same as the shape of the winding portion 426B when seen in the direction of the coil axis Ax2. In this manner, the inductor including the winding portion 426A can have the same electrical and magnetic characteristics as the inductor including the winding portion 426B. Since the winding portions 426A and 426B have the same shape, the inductor including the winding portion 426A and the inductor including the winding portion 426B can behave in the same manner responding to external factors (for example, electromagnetic influence made by external devices). Specifically, the winding portion 426B is wound around the coil axis Ax2 a predetermined number of turns. The winding portion 426B may be wound 1.5 turns or less. In the embodiment shown in FIG. 19B, the winding pattern 426B1 extends approximately 0.75 turns) (270° around the coil axis Ax2 from its connection with the lead-out conductor 427B1 to its connection with the via VB, and the winding pattern 426B2 extends approximately 0.75 turns) (270° around the coil axis Ax2 from its connection with the via VB to its connection with the lead-out conductor 427B2. In this manner, the winding portion 426B is wound around the coil axis Ax2 approximately 1.5 turns) (540°.

A core region 410B denotes a region of the base body 10 that is enclosed within the winding portion 426B when seen in the L-axis direction. In one embodiment, the coil axis Ax2 passes through the geometric center of the core region 410B when seen in the L-axis direction and extends in the direction parallel to the mounting surface 10b. The description on the core region 410A also applies to the core region 410B to a maximum extent.

Next, a description is given of the internal conductors 425A and 425B with further reference to FIG. 18. FIG. 18 is a sectional view schematically showing the section of the inductor array 401 along the V-V line. The section shown in FIG. 18 is obtained by cutting the inductor array 401 with a plane passing through the coil axis Ax1 and perpendicular to the second principal surface 10b. As shown in FIG. 18, in one or more embodiments of the present invention, coil axes Ax1 and Ax2 extend parallel to the mounting surface 10b. The coil axes Ax1 and Ax2 may be orthogonal to at least one of the first end surface 10c or the second end surface 10d. As used herein, the terms “parallel,” “orthogonal” or “perpendicular” are not intended to mean solely “parallel,” “orthogonal” or “perpendicular” in a mathematically strict sense. In one or more embodiments of the present invention, the coil axis Ax1 is positioned away by a first distance T1 from the mounting surface 10b, and the coil axis Ax2 is positioned away by a second distance T2 greater than the first distance T1 from the mounting surface 10b. In other words, the second distance T2 between the coil axis Ax2 and the mounting surface 10b is greater than the first distance T1 between the coil axis Ax1 and the mounting surface 10b.

As shown in FIG. 18, in one or more embodiments of the present invention, the internal conductors 425A and 425B are arranged such that the coil axis Ax1 extends through not only the core region 410A within the internal conductor 425A but also the core region 410B within the internal conductor 425B and the coil axis Ax2 extends through not only the core region 410B within the internal conductor 425B but also the core region 410A within the internal conductor 425A. Such arrangement can reduce an increase in size in the T-axis direction of the inductor array 401.

In one or more embodiments of the present invention, a dimension a2 of the winding portion 426A in the L-axis direction (the dimension in the direction extending along the coil axis Ax1) is less than its dimension D1 in the T axis direction (the dimension in the direction orthogonal to the coil axis Ax1). Likewise, in one or more embodiments of the present invention, a dimension in the L-axis direction of the winding portion 426B (the dimension in the direction extending along the coil axis Ax2) is less than its dimension in the T axis direction (the dimension in the direction orthogonal to the coil axis Ax2). As the size of the internal conductors 425A and 425B in the direction extending along the mounting surface 10b is reduced as described above, the inductor array 401 can achieve a reduced size in the direction extending along the mounting surface 10b.

In one or more embodiments of the present invention, the internal conductor 425B is spaced away from the internal conductor 425A by a distance G1 in the direction extending along the coil axis Ax1. In other words, the spacing between the internal conductors 425A and 425B in the direction extending along the coil axis Ax1 is the distance denoted by the reference sign G1. The spacing G1 between the internal conductors 425A and 425B is the distance in the L-axis direction between the negative-side end of the internal conductor 425A in the L-axis direction and the positive-side end of the internal conductor 425B in the L-axis direction. In one or more embodiments of the invention, the spacing G1 between the internal conductors 425A and 425B is 0.3 mm or less.

Next, a description is given of the winding portions 426A and 426B with further reference to FIG. 20A. FIG. 20A is an enlarged view showing a part of the section of FIG. 18. As shown in FIG. 20A, the section of the winding patterns 426A1 and 426A2 obtained by cutting them along the plane passing through the coil axis Ax1 and perpendicular to the mounting surface 10b is shaped like a rectangle. As used herein, the section of the winding portion 426A or winding patterns 426A1 and 426A2 obtained by cutting them along the plane passing through the coil axis Ax1 and perpendicular to the mounting surface 10b may be simply referred to as the “section” of the winding portion 426A or winding patterns 426A1 and 426A2 without identifying the cutting plane for the sake of simplifying the description.

When a1 and a2 respectively refer to the dimension in the direction perpendicular to coil axis Ax1 and the dimension in the direction parallel to the coil axis Ax1 of the section of the winding portion 426A obtained by cutting the winding portion 426A along a plane orthogonal to the direction of the electric current flow through the internal conductor 425A, the ratio of a1 to a2 (a1/a2) may be referred to as a first aspect ratio of the internal conductor 425A, similarly to the case of the internal conductor 25A. When the winding portion 426A has winding patterns in two or more layers, the dimension a2 of the section of the winding portion 426A in the direction parallel to the coil axis Ax1 indicates the distance between (i) one of the outermost ends of the winding patterns in the direction of the coil axis Ax1 and (ii) the other of the outermost ends of the winding patterns in the direction of the coil axis Ax1. In the embodiment shown, the winding portion 426A has the winding patterns 426A1 and 426A2, and the distance between (i) one of the ends in the direction extending along the coil axis Ax1 of the winding pattern 426A1 (the left end in FIG. 20A) and (ii) the other end in the direction extending along the coil axis Ax1 of the winding pattern 426A2 (the right end in FIG. 20A) represents the dimension a2 in the direction parallel to the coil axis Ax1 of the section of the winding portion 426A.

The first aspect ratio of the internal conductor 425A is greater than one. In other words, the dimension a1 of the section of the winding portion 426A in the direction perpendicular to the coil axis Ax1 is greater than the dimension a2 of the section of the winding portion 426A in the direction parallel to the coil axis Ax1. In the embodiment shown, the first aspect ratio is approximately 1.3. The first aspect ratio may be greater than 1.1, 1.2, 1.3, 1.4, 1.5, 2.0, 5.0 or 10.0.

In the embodiment shown, the section of the winding patterns 426B1 and 426B2 obtained by cutting them along the plane passing through the coil axis Ax2 and perpendicular to the mounting surface 10b is also shaped like a rectangle. As used herein, the section of the winding portion 426B or winding patterns 426B1 and 426B2 obtained by cutting them along the plane passing through the coil axis Ax2 and perpendicular to the mounting surface 10b may be simply referred to as the “section” of the winding portion 426B or winding patterns 426B1 and 426B2 without identifying the cutting plane for the sake of simplifying the description.

When b1 and b2 respectively refer to the dimension in the direction perpendicular to the coil axis Ax2 and the dimension in the direction parallel to the coil axis Ax2 of the section of the winding portion 426B obtained by cutting the winding portion 426B along a plane orthogonal to the direction of the electric current flow through the internal conductor 425B, the ratio of b1 to b2 (b1/b2) may be referred to as a second aspect ratio of the internal conductor 425B, similarly to the case of the internal conductor 25B. When the winding portion 426B has winding patterns in two or more layers, the dimension b2 of the section of the winding portion 426B in the direction parallel to the coil axis Ax2 indicates the distance between (i) one of the outermost ends of the winding patterns in the direction of the coil axis Ax2 and (ii) the other of the outermost ends of the winding patterns in the direction of the coil axis Ax2. In the embodiment shown, the winding portion 426B has the winding patterns 426B1 and 426B2, and the distance between (i) one of the ends in the direction extending along the coil axis Ax2 of the winding pattern 426B1 (the left end in FIG. 20A) and (ii) the other end in the direction extending along the coil axis Ax2 of the winding pattern 426B2 (the right end in FIG. 20A) represents the dimension b2 in the direction parallel to the coil axis Ax2 of the section of the winding portion 426B. In one or more embodiments of the invention, the second aspect ratio is greater than one. In other words, the dimension b1 of the section of the winding portion 426B in the direction perpendicular to the coil axis Ax2 is greater than the dimension b2 of the section of the winding portion 426B in the direction parallel to the coil axis Ax2. In the embodiment shown, the second aspect ratio is approximately 1.3. The second aspect ratio of the internal conductor 425B may be greater than 1.1, 1.2, 1.3, 1.4, 1.5, 2.0, 5.0 or 10.0. The first and second aspect ratios may be the same or different.

In one or more embodiments of the invention, when at least one of the first aspect ratio or the second aspect ratio is greater than one, the first distance T1 and the second distance T2 may be equal to each other. In other words, when at least one of the first aspect ratio or the second aspect ratio is greater than one, the internal conductors 425A and 425B may be arranged such that the coil axes Ax1 and Ax2 are coincident with each other.

Modifications of the internal conductors 425A and 425B will be hereinafter described with reference to FIG. 20B. The winding patterns 426A1 and 426A2 and lead-out conductors 427A1 and 427A2 constituting the internal conductor 425A may each include a plurality of conductor layers. FIG. 20B shows an embodiment where the winding patterns 426A1 and 426A2 and lead-out conductors 427A1 and 427A2 each have two conductor layers having the same shape. As shown, the winding pattern 426A1 has a first winding pattern 426A1a and a second winding pattern 426A1b positioned opposite the first winding pattern 426A1a and having the same shape as the first winding pattern 426A1a. The first and second winding patterns 426A1a and 426A1b may be electrically connected to each other within the base body 10. Likewise, the winding pattern 426A2 has a first winding pattern 426A2a and a second winding pattern 426A2b positioned opposite the first winding pattern 426A2a and having the same shape as the first winding pattern 426A2a. The first and second winding patterns 426A2a and 426A2b may be electrically connected to each other within the base body 10. Although not shown in the drawing, the lead-out conductor 427A1 may also have two conductor layers having the same shape, as noted. The conductor layers constituting the lead-out conductor 427A1 may be also electrically connected to each other within the base body 10. The lead-out conductor 427A2 also has two conductor layers having the same shape. The conductor layers constituting the lead-out conductor 427A2 may be also electrically connected to each other within the base body 10. Since the conductor layers included in the winding patterns 426A1 and 426A2 and the lead-out conductors 427A1 and 427A2, together constituting the internal conductor 425A, have the same shape, there is no difference in potential between such parts of the conductor layers that are opposed to each other in the base body 10. Thus, even in a case where the winding patterns 426A1 and 426A2 and the lead-out conductors 427A1 and 427A2, together constituting the internal conductor 425A, are each made up by a plurality of conductor layers, a level of insulation reliability (withstand voltage) required of the base body 10 can be the same as in a case where the internal conductor 425A is formed of a single conductor portion.

As in the case of the internal conductor 425A, the winding patterns 426B1 and 426B2 and lead-out conductors 427B1 and 427B2 constituting the internal conductor 425B may each include a plurality of conductor layers. FIG. 20B shows an embodiment where the winding patterns 426B1 and 426B2 and lead-out conductors 427B1 and 427B2 each have two conductor layers having the same shape. As shown, the winding pattern 426B1 has a first winding pattern 426B1a and a second winding pattern 426B1b positioned opposite the first winding pattern 426B1a and having the same shape as the first winding pattern 426B1a. The first and second winding patterns 426B1a and 426B1b may be electrically connected to each other within the base body 10. Likewise, the winding pattern 426B2 has a first winding pattern 426B2a and a second winding pattern 426B2b positioned opposite the first winding pattern 426B2a and having the same shape as the first winding pattern 426B2a. The first and second winding patterns 426B2a and 426B2b may be electrically connected to each other within the base body 10. Although not shown in the drawing, the lead-out conductor 427B1 may also have two conductor layers having the same shape, as noted. The conductor layers constituting the lead-out conductor 427B1 may be also electrically connected to each other within the base body 10. The lead-out conductor 427B2 also has two conductor layers having the same shape. The conductor layers constituting the lead-out conductor 427B2 may be also electrically connected to each other within the base body 10.

As shown in FIG. 20B, when the winding patterns 426A1 and 426A2 each have a plurality of conductor layers, the dimension a2 in the direction parallel to the coil axis Ax1 of the section of the winding portion 426A refers to the distance between (i) one end in the direction extending along the coil axis Ax1 of the outermost one (the far left one in FIG. 20B) of the conductor layers constituting the winding pattern 426A1 and (ii) the other end in the direction extending along the coil axis Ax1 of the outermost one (the far right one in FIG. 20B) of the conductor layers constituting the winding pattern 426A2. Likewise, when the winding patterns 426B1 and 426B2 each have a plurality of conductor layers, the dimension b2 in the direction parallel to the coil axis Ax2 of the section of the winding portion 426B refers to the distance between (i) one end in the direction extending along the coil axis Ax2 of the outermost one (the far left one in FIG. 20B) of the conductor layers constituting the winding pattern 426B1 and (ii) the other end in the direction extending along the coil axis Ax2 of the outermost one (the far right one in FIG. 20B) of the conductor layers constituting the winding pattern 426B2.

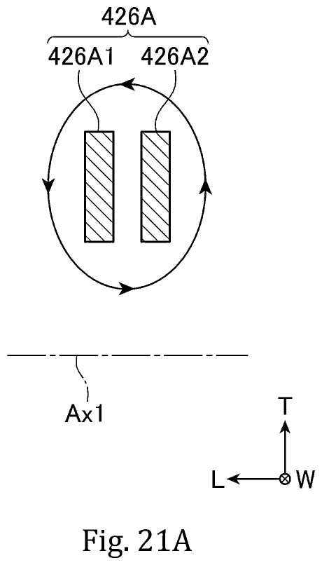

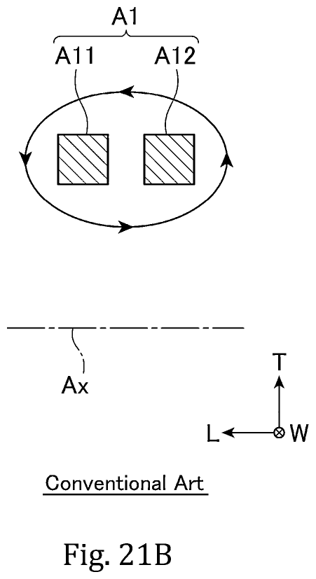

Next, a description is given of the magnetic flux generated around the winding portion 426A by a change in current flowing through the internal conductor 425A with further reference to FIGS. 21A and 21B. FIG. 21A schematically shows the magnetic flux generated by a change in current flowing through the winding portion 426A of the internal conductor 425A, and FIG. 21B schematically shows the magnetic flux generated by a change in current flowing through a conventional internal conductor, which has a winding portion A1 wound around a coil axis Ax. The winding portion A1 shown in FIG. 21B has winding patterns A11 and A12. It is assumed that the winding pattern A11 is connected to the winding pattern A12 through a via so that the winding patterns A11 and A12 constitute the winding portion A1. The section of the winding patterns A11 and A12 has a square shape having the same area as the section of the winding patterns 426A1 and 426A2. The ratio of the dimension of the section of the winding portion A1 in the direction perpendicular to the coil axis Ax to the dimension of the section of the winding portion A1 in the direction parallel to the coil axis Ax is less than one. As shown in FIG. 21A, the magnetic flux generated around the winding portion 426A, which is wound around the coil axis Ax1, in response to a change in current flowing through the internal conductor 425A is more likely to be directed perpendicularly to the coil axis Ax1 since the first aspect ratio is greater than one. As shown in FIG. 21B, on the other hand, the magnetic flux generated around the winding portion A1, which has an aspect ratio of less than one and is wound around the coil axis Ax, is more likely to be directed parallel to the coil axis Ax. As shown, when the first aspect ratio of the winding patterns 426A1 and 426A2 is greater than one, the magnetic flux generated around the winding patterns 426A1 and 426A2 responding to a change in current flowing through the internal conductor 425A is less likely to reach other internal conductors adjacent to the internal conductor 425A in the direction extending along the coil axis Ax1 (for example, the internal conductor 425B). Stated differently, when the first aspect ratio of the winding patterns 426A1 and 426A2 of the winding portion 426A included in the internal conductor 425A is set greater than one, this configuration can reduce magnetic coupling between the internal conductor 425A and other internal conductor adjacent to the internal conductor 425A in the direction extending along the coil axis Ax1 (for example, the internal conductor 425B). In one or more embodiments of the invention, the absolute value of the coefficient of the coupling between the internal conductors 425A and 425B is 0.15 or less. In one or more embodiments of the invention, the absolute value of the coefficient of the coupling between the internal conductors 425A and 425B can be 0.15 or less even when the distance between the internal conductors 425A and 425B is 0.3 mm or less. In one or more embodiments of the invention, the absolute value of the coefficient of the coupling between the internal conductors 425A and 425B is 0.15 or less, so that the internal conductors 425A and 425B each can stably exhibit their own characteristics without being disturbed by electromagnetic interference from the other internal conductor. Since the internal conductors 425A and 425B included in the inductor array 1 can each avoid electromagnetic interference from the other internal conductor, the internal conductors 425A and 425B can each exhibit their own characteristics even with a small pitch (for example, 0.2 mm or less) of the wirings of the circuit having the inductor array 1 installed therein. For example, in a circuit where the inductor array 401 is connected to a plurality of semiconductor devices (for example, power transistors), the internal conductors 425A and 425B can each provide an independent power source to each of the semiconductor devices.

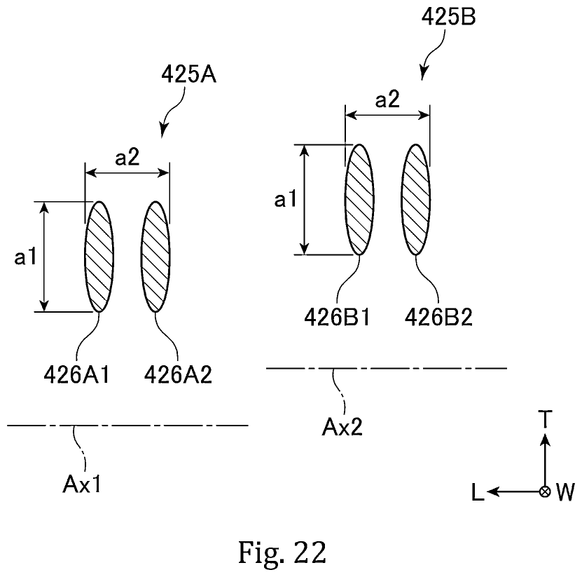

Subsequently, an inductor array according to another embodiment of the invention will be described with reference to FIGS. 22 to 28.

Next, a description is given of a modification example of the internal conductors 425A and 425B with further reference to FIG. 22. In the embodiment shown in FIG. 22, the winding patterns 426A1, 426A2, 426B1 and 426B2 have a rounded section. In other words, the winding patterns 426A1, 426A2, 426B1 and 426B2 have a section the outer edge of which is defined only by a curved line. The winding patterns 426A1, 426A2, 426B1 and 426B2 may have a section shaped like an ellipse as shown in FIG. 22 or any other shapes (for example, an oval). Since the winding patterns 426A1, 426A2, 426B1 and 426B2 have a rounded section, the magnetic flux generated around the winding patterns 426A1, 426A2, 426B1 and 426B2 follows a magnetic path closer to the center of the section of the respective winding patterns. This can reduce magnetic coupling between the internal conductor 425A including the winding patterns 426A1 and 426A2 and the internal conductor 425B including the winding patterns 426B1 and 426B2. In one or more embodiments of the present invention, only one or some of the winding patterns 426A1, 426A2, 426B1 and 426B2 may have a rounded section. In one or more embodiments of the present invention, the winding pattern 426A2 may have a rounded section, and the winding pattern 426A1 may have a sharp-edged section (for example, the rectangular section shown in FIG. 20A). The winding pattern 426A2 opposes the internal conductor 425B. If the winding pattern 426A2 has a rounded section, the magnetic flux is generated around the winding pattern 426A2 such that it follows a magnetic path closer to the center of the section of the winding pattern 426A2. This can reduce magnetic coupling between the internal conductor 425A and the internal conductor 425B. On the other hand, the winding pattern 426A1 does not oppose the internal conductor 425B but opposes the outer surface of the base body 10. Accordingly, even if the winding pattern 426A1 has a sharp-edged section, this shape does not contribute much to enforce the magnetic coupling between the internal conductors 425A and 425B. For similar reasons, in one or more embodiments of the present invention, the winding pattern 426B1 may have a rounded section, and the winding pattern 426B2 may have a sharp-edged section.

The shape of the section of the winding patterns 426A1, 426A2, 426B1 and 426B2 is not limited to the above-described shapes. The winding patterns 426A1, 426A2, 426B1 and 426B2 may have a section shaped like, for example, a circle, a rectangle, a polygon other than a rectangle. In embodiments where the first aspect ratio of the winding patterns 426A1, 426A2, 426B1 and 426B2 is greater than one, the section of the winding patterns 426A1, 426A2, 426B1 and 426B2 has a shape other than a circle and a square. The winding patterns 426A1 and 426A2, may have the same or different shapes as/from the winding patterns 426B1 and 426B2.

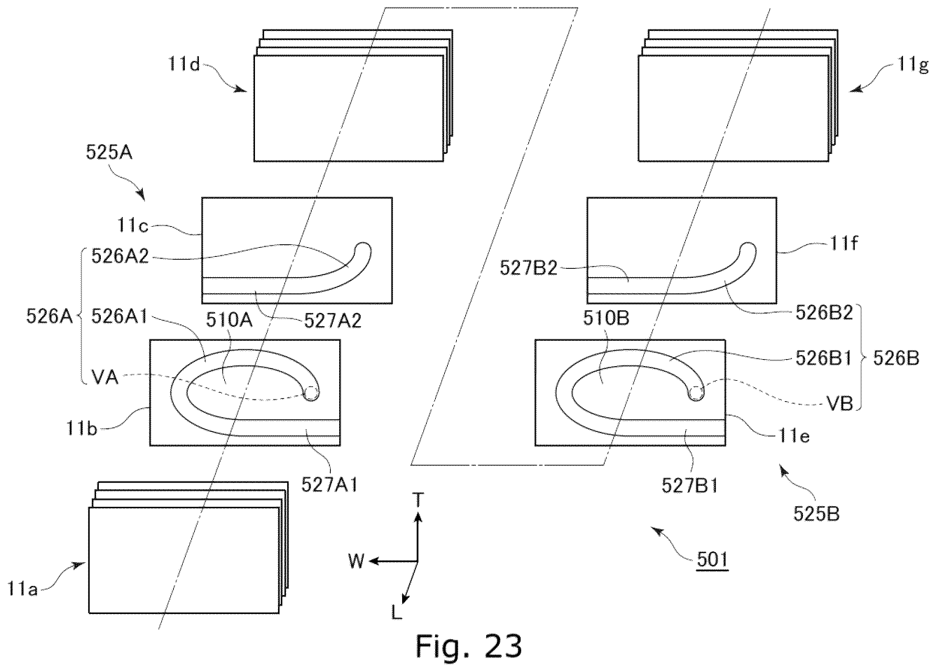

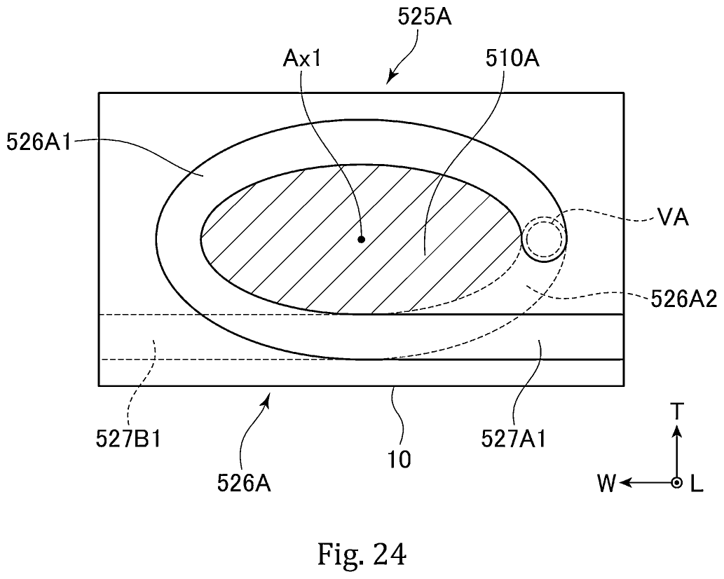

Subsequently, an inductor array 501 according to one or more embodiments of the present invention will be described with reference to FIGS. 23 and 24. The inductor array 501 shown in FIGS. 23 and 24 is different from the inductor array 401 in that it includes, instead of the internal conductors 425A and 425B, internal conductors 525A and 525B. The following description does not mention the similarities between the inductor arrays 501 and 401.

The inductor array 501 includes the internal conductors 525A and 525B. In the embodiment illustrated, the internal conductor 525A includes a winding portion 526A, a lead-out conductor 527A1 and a lead-out conductor 527A2. The winding portion 526A extends in a circumferential direction around a coil axis Ax1 extending in a direction parallel to the mounting surface 10b of the base body 10. The winding portion 526A includes a winding pattern 526A1 provided on one of the surfaces of the magnetic layer 11b intersecting the L-axis, or the positive-side surface in the L-axis direction, a winding pattern 526A2 provided on one of the surfaces of the magnetic layer 11c intersecting the L-axis, or the positive-side surface in the L-axis direction, and a via VA provided in the magnetic layer 11b. The winding patterns 526A1 and 526A2 are connected together through the via VA. The winding portion 526A is wound around the coil axis Ax1 approximately 1 turn.

The lead-out conductor 527A1 extends on the magnetic layer 11b along the W axis, and is connected at one of the ends thereof to the winding pattern 526A1 and at the other end thereof to the external electrode 21A (not shown in FIGS. 23 and 24). The lead-out conductor 527A2 extends on the magnetic layer 11c along the W axis, and is connected at one of the ends thereof to the winding pattern 526A2 and at the other end thereof to the external electrode 22A (not shown in FIGS. 23 and 24).

In the embodiment illustrated, the internal conductor 525B includes a winding portion 526B, a lead-out conductor 527B1 and a lead-out conductor 527B2. The winding portion 526B extends in a circumferential direction around a coil axis Ax2 extending in a direction parallel to the mounting surface 10b of the base body 10. The winding portion 526B includes a winding pattern 526B1 provided on one of the surfaces of the magnetic layer 11e intersecting the L-axis, or the positive-side surface in the L-axis direction, a winding pattern 526B2 provided on one of the surfaces of the magnetic layer 11f intersecting the L-axis, or the positive-side surface in the L-axis direction, and a via VB provided in the magnetic layer 11e. The winding patterns 526B1 and 526B2 are connected together through the via VB. The winding portion 526B is wound around the coil axis Ax2 approximately 1 turn.

The lead-out conductor 527B1 extends on the magnetic layer 11e along the W axis, and is connected at one of the ends thereof to the winding pattern 526B1 and at the other end thereof to the external electrode 21B (not shown in FIGS. 23 and 24). The lead-out conductor 527B2 extends on the magnetic layer 11f along the W axis, and is connected at one of the ends thereof to the winding pattern 526B2 and at the other end thereof to the external electrode 22B (not shown in FIGS. 23 and 24).

The winding patterns 526A1, 526A2, 526B1 and 526B2 and lead-out conductors 527A1, 527A2, 527B1 and 527B2 may be made of a conductive paste, like the winding patterns 426A1, 426A2, 426B1 and 426B2 and lead-out conductors 427A1, 427A2, 427B1 and 427B2.

A core region 510A denotes a region of the base body 10 that is enclosed within the winding portion 526A when seen in the L-axis direction. In one embodiment, the coil axis Ax1 passes through the geometric center of the core region 510A when seen in the L-axis direction and extends in the direction parallel to the mounting surface 10b. A core region 510B denotes a region of the base body 10 that is enclosed within the winding portion 526B when seen in the L-axis direction. In one embodiment, the coil axis Ax2 passes through the geometric center of the core region 510B when seen in the L-axis direction and extends in the direction parallel to the mounting surface 10b. In the inductor array 501, the coil axis Ax1 is also positioned away by a first distance T1 from the mounting surface 10b, and the coil axis Ax2 is also positioned away by a second distance T2 greater than the first distance T1 from the mounting surface 10b.

The description made regarding the section of the winding patterns 426A1 and 426A2 also applies to the section of the winding patterns 526A1 and 526A2 that is obtained by cutting them along a plane passing through the coil axis Ax1 and perpendicular to the mounting surface 10b, and the description made regarding the section of the winding patterns 426B1 and 426B2 also applies to the section of the winding patterns 526B1 and 526B2 that is obtained by cutting them along a plane passing through the coil axis Ax2 and perpendicular to the mounting surface 10b.

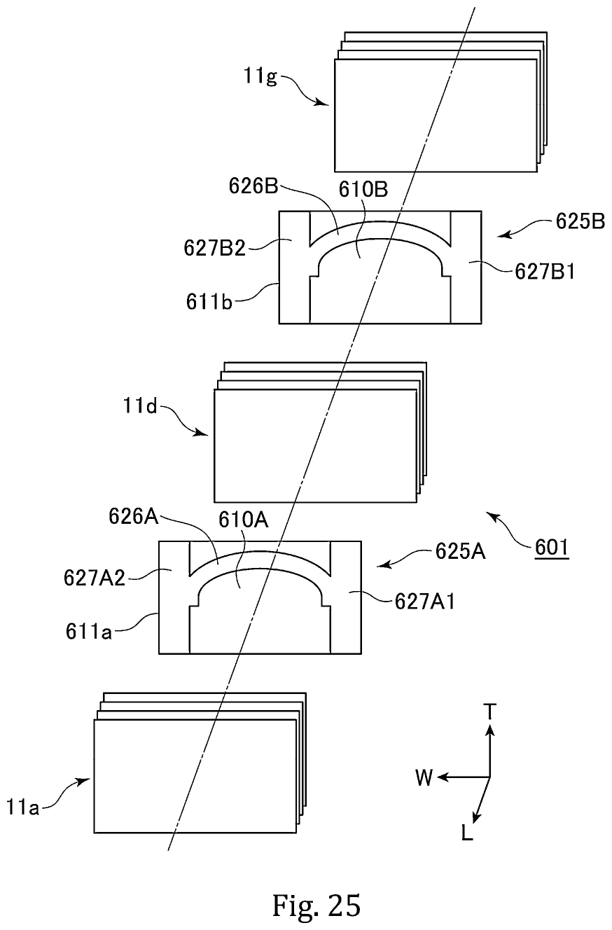

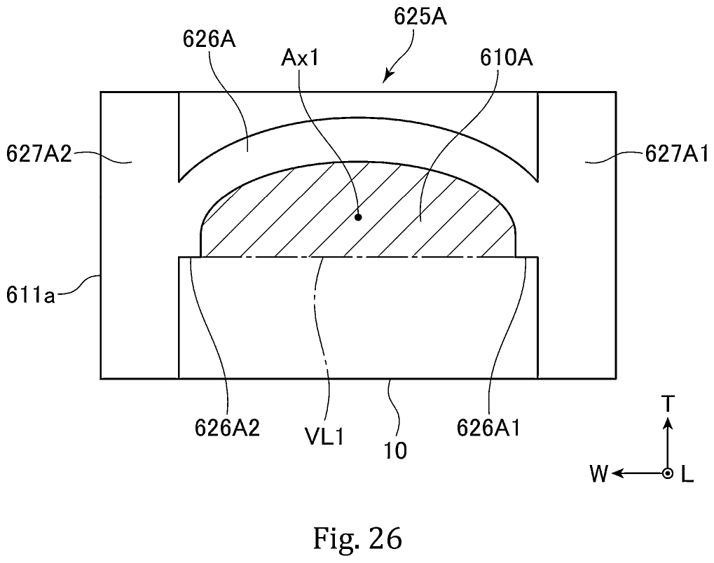

Subsequently, an inductor array 601 according to one or more embodiments of the present invention will be described with reference to FIGS. 25 and 26. The inductor array 601 shown in FIGS. 25 and 26 is different from the inductor array 401 in that it includes a magnetic layer 611a in place of the magnetic layers 11b and 11c, includes a magnetic layer 611b in place of the magnetic layers 11e and 11f and includes internal conductors 625A and 625B in place of the internal conductors 425A and 425B. The following description does not mention the similarities between the inductor arrays 601 and 401.

As illustrated, in the inductor array 601, the magnetic layer 611a is provided between the magnetic layers 11a and 11d, and the magnetic layer 611b is provided between the magnetic layers 11d and 11g. The magnetic layers 611a and 611b may be made in the same manner as the magnetic layers 11a to 11g.

In the embodiment illustrated, the internal conductor 625A includes a winding portion 626A, a lead-out conductor 627A1 and a lead-out conductor 627A2. The winding portion 626A extends in a circumferential direction around a coil axis Ax1 extending in a direction parallel to the mounting surface 10b of the base body 10. The winding portion 626A and lead-out conductors 627A1 and 627A2 are provided on one of the surfaces of the magnetic layer 611a intersecting the L-axis, or the positive-side surface in the L-axis direction. The winding portion 626A is wound around the coil axis Ax1 approximately 0.5 turns. The lead-out conductor 627A1 extends along the first side surface 10e from the bottom end thereof to the top end thereof. The lead-out conductor 627A2 extends along the second side surface 10f from the bottom end thereof to the top end thereof. The lead-out conductor 627A1 is connected to the external electrode 21A, and the lead-out conductor 627A2 is connected to the external electrode 22A. In FIGS. 25 and 26, the external electrodes 21A and 22A are not shown.

In the embodiment illustrated, the internal conductor 625B includes a winding portion 626B, a lead-out conductor 627B1 and a lead-out conductor 627B2. The winding portion 626B extends in a circumferential direction around a coil axis Ax2 extending in a direction parallel to the mounting surface 10b of the base body 10. The winding portion 626B and lead-out conductors 627B1 and 627B2 are provided on one of the surfaces of the magnetic layer 611b intersecting the L-axis, or the positive-side surface in the L-axis direction. The winding portion 626B is wound around the coil axis Ax2 approximately 0.5 turns. The lead-out conductor 627B1 extends along the first side surface 10e from the bottom end thereof to the top end thereof. The lead-out conductor 627B2 extends along the second side surface 10f from the bottom end thereof to the top end thereof. The lead-out conductor 627B1 is connected to the external electrode 21B, and the lead-out conductor 627B2 is connected to the external electrode 22B. In FIGS. 25 and 26, the external electrodes 21B and 22B are not shown.

The winding portions 626A and 626B and lead-out conductors 627A1, 627A2, 627B1 and 627B2 may be made of a conductive paste, like the winding patterns 426A1, 426A2, 426B1 and 426B2 and lead-out conductors 427A1, 427A2, 427B1 and 427B2.

A core region 610A denotes a region of the base body 10 that is enclosed within the winding portion 626A when seen in the L-axis direction. More specifically, the core region 610A denotes a region defined by (i) an imaginary line VL1 connecting together an end 626A1 and an end 626A2 of the winding portion 626A, where the ends 626A1 and 626A2 are defined in the circumferential direction around the coil axis Ax1, and (ii) the internal circumferential surface of the winding portion 626A. In one embodiment, the coil axis Ax1 passes through the geometric center of the core region 610A when seen in the L-axis direction and extends in the direction parallel to the mounting surface 10b. A core region 610B denotes a region of the base body 10 that is enclosed within the winding portion 626B when seen in the L-axis direction. Like the core region 610A, the core region 610B may denote a region defined by (i) an imaginary line connecting together the ends of the winding portion 626B, where the ends are defined in the circumferential direction around the coil axis Ax2, and (ii) the internal circumferential surface of the winding portion 626B. In one embodiment, the coil axis Ax2 passes through the geometric center of the core region 610B when seen in the L-axis direction and extends in the direction parallel to the mounting surface 10b. In the inductor array 601, the coil axis Ax1 is also positioned away by a first distance T1 from the mounting surface 10b, and the coil axis Ax2 is also positioned away by a second distance T2 greater than the first distance T1 from the mounting surface 10b.

The description made regarding the section of the winding patterns 426A1 and 426A2 also applies to the section of the winding portion 626A that is obtained by cutting it along a plane passing through the coil axis Ax1 and perpendicular to the mounting surface 10b, and the description made regarding the section of the winding patterns 426B1 and 426B2 also applies to the section of the winding portion 626B that is obtained by cutting it along a plane passing through the coil axis Ax2 and perpendicular to the mounting surface 10b.

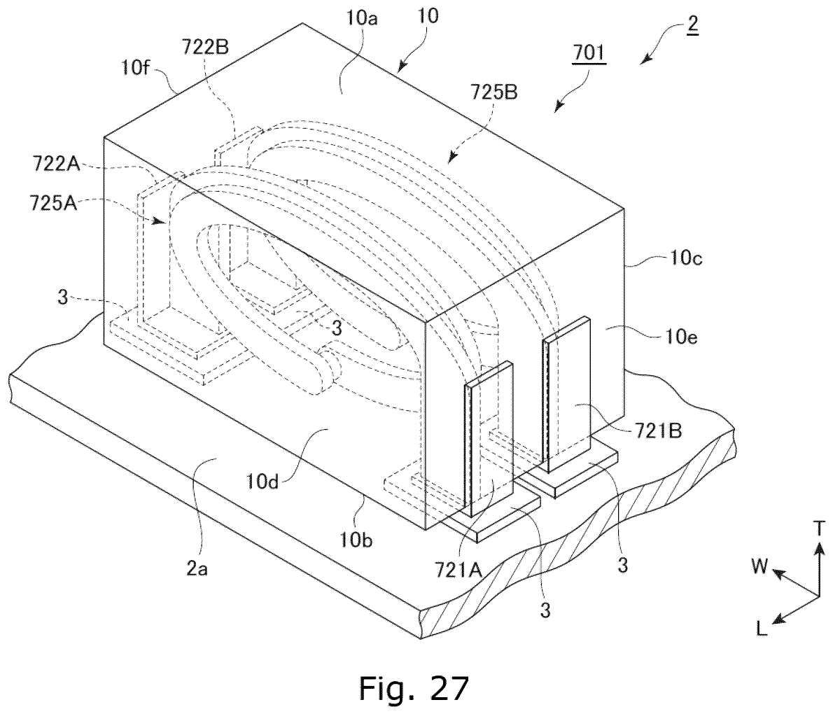

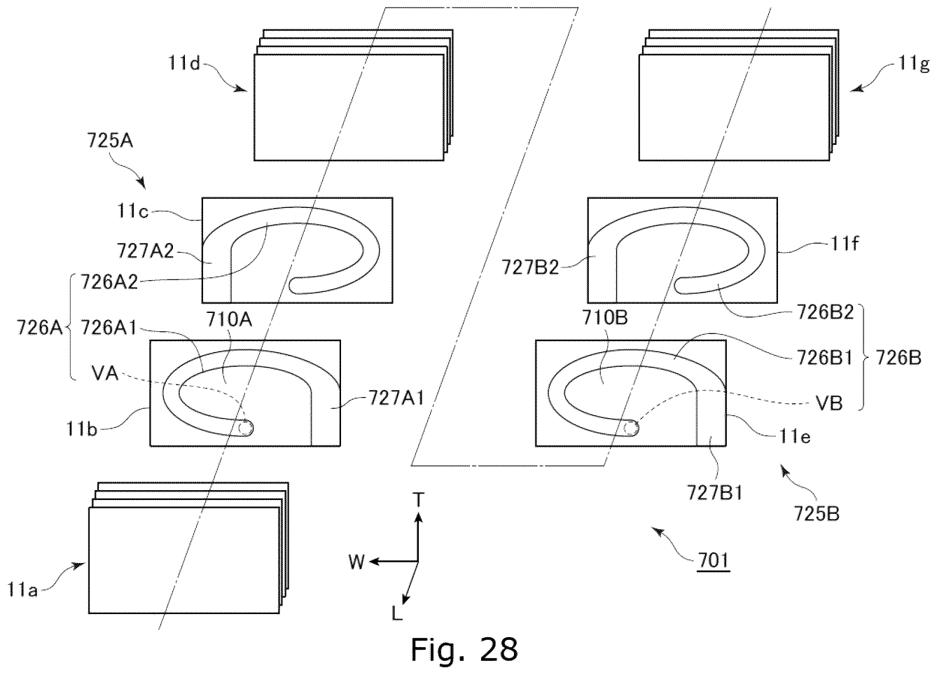

Subsequently, an inductor array 701 according to one or more embodiments of the present invention will be described with reference to FIGS. 27 and 28. The inductor array 701 shown in FIGS. 27 and 28 is different from the inductor array 401 in that it includes, instead of the external electrodes 21A, 21B, 22A, 22B, external electrodes 721A, 721B, 722A and 722B, and that it includes internal conductors 725A and 725B in place of the internal conductors 425A and 425B. The following description does not mention the similarities between the inductor arrays 701 and 401.

As illustrated, the external electrodes 721A and 721B are L-shaped when seen in the L-axis direction and in contact with the mounting surface 10b and first side surface 10e of the base body 10. The external electrodes 722A and 722B are L-shaped when seen in the L-axis direction and in contact with the mounting surface 10b and second side surface 10f of the base body 10.

In the embodiment illustrated, the internal conductor 725A includes a winding portion 726A, a lead-out conductor 727A1 and a lead-out conductor 727A2. The winding portion 726A extends in a circumferential direction around a coil axis Ax1 extending in a direction parallel to the mounting surface 10b of the base body 10. The winding portion 726A includes a winding pattern 726A1 provided on one of the surfaces of the magnetic layer 11b intersecting the L-axis, or the positive-side surface in the L-axis direction, a winding pattern 726A2 provided on one of the surfaces of the magnetic layer 11c intersecting the L-axis, or the positive-side surface in the L-axis direction, and a via VA provided in the magnetic layer 11b. The winding patterns 726A1 and 726A2 are connected together through the via VA. The winding portion 726A is wound around the coil axis Ax1 approximately 1.5 turns.

The lead-out conductor 727A1 extends on the magnetic layer 11b along the T axis and is connected at one of the ends thereof to the winding pattern 726A1. The lead-out conductor 727A1 is partially exposed to the outside of the base body 10 through the first side surface 10e and mounting surface 10b and the exposed portion is connected to the external electrode 721A. The lead-out conductor 727A2 extends on the magnetic layer 11c along the T axis and is connected at one of the ends thereof to the winding pattern 726A2. The lead-out conductor 727A2 is partially exposed to the outside of the base body 10 through the second side surface 10f and mounting surface 10b, and the exposed portion is connected to the external electrode 722A.

In the embodiment illustrated, the internal conductor 725B includes a winding portion 726B, a lead-out conductor 727B1 and a lead-out conductor 727B2. The winding portion 726B extends in a circumferential direction around a coil axis Ax2 extending in a direction parallel to the mounting surface 10b of the base body 10. The winding portion 726B includes a winding pattern 726B1 provided on one of the surfaces of the magnetic layer 11e intersecting the L-axis, or the positive-side surface in the L-axis direction, a winding pattern 726B2 provided on one of the surfaces of the magnetic layer 11f intersecting the L-axis, or the positive-side surface in the L-axis direction, and a via VB provided in the magnetic layer 11e. The winding patterns 726B1 and 726B2 are connected together through the via VB. The winding portion 726B is wound around the coil axis Ax2 approximately 1.5 turns.

The lead-out conductor 727B1 extends on the magnetic layer 11e along the T axis, and is connected at one of the ends thereof to the winding pattern 726B1. The lead-out conductor 727B1 is partially exposed to the outside of the base body 10 through the first side surface 10e and mounting surface 10b, and the exposed portion is connected to the external electrode 721B. The lead-out conductor 727B2 extends on the magnetic layer 11f along the T axis, and is connected at one of the ends thereof to the winding pattern 726B2. The lead-out conductor 727B2 is partially exposed to the outside of the base body 10 through the second side surface 10f and mounting surface 10b, and the exposed portion is connected to the external electrode 722B.

The winding patterns 726A1, 726A2, 726B1 and 726B2 and lead-out conductors 727A1, 727A2, 727B1 and 727B2 may be made of a conductive paste, like the winding patterns 426A1, 426A2, 426B1 and 426B2 and lead-out conductors 427A1, 427A2, 427B1 and 427B2.

A core region 710A denotes a region of the base body 10 that is enclosed within the winding portion 726A when seen in the L-axis direction. In one embodiment, the coil axis Ax1 passes through the geometric center of the core region 710A when seen in the L-axis direction and extends in the direction parallel to the mounting surface 10b. A core region 710B denotes a region of the base body 10 that is enclosed within the winding portion 726B when seen in the L-axis direction. In one embodiment, the coil axis Ax2 passes through the geometric center of the core region 710B when seen in the L-axis direction and extends in the direction parallel to the mounting surface 10b. In the inductor array 701, the coil axis Ax1 is also positioned away by a first distance T1 from the mounting surface 10b, and the coil axis Ax2 is also positioned away by a second distance T2 greater than the first distance T1 from the mounting surface 10b.

The description made regarding the section of the winding patterns 426A1 and 426A2 also applies to the section of the winding patterns 726A1 and 726A2 that is obtained by cutting them along a plane passing through the coil axis Ax1 and perpendicular to the mounting surface 10b, and the description made regarding the section of the winding patterns 426B1 and 426B2 also applies to the section of the winding patterns 726B1 and 726B2 that is obtained by cutting them along a plane passing through the coil axis Ax2 and perpendicular to the mounting surface 10b.

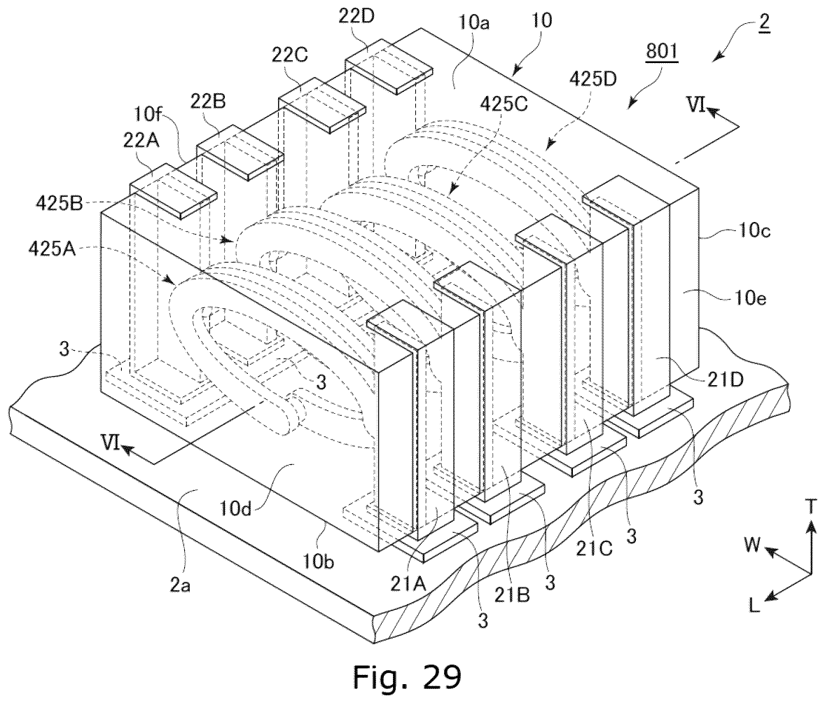

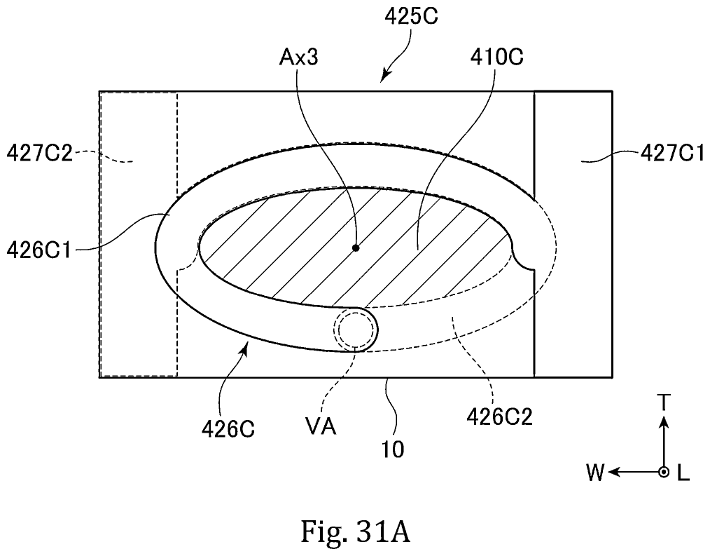

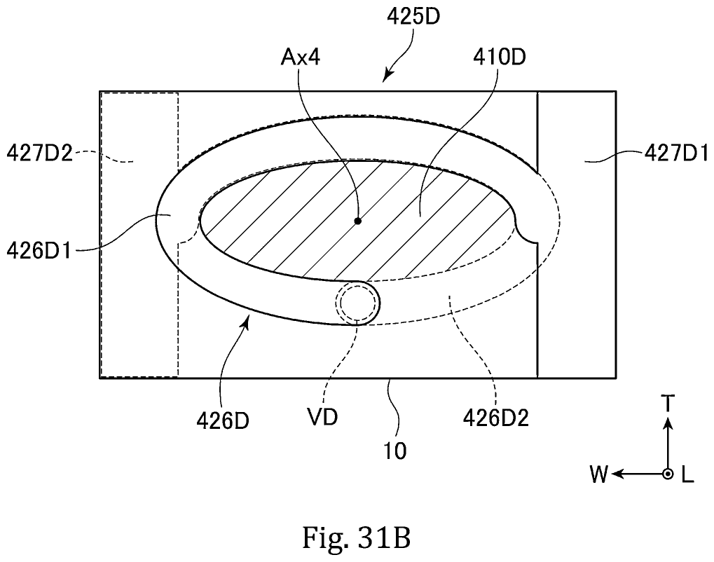

Subsequently, an inductor array 801 according to one or more embodiments of the present invention will be described with reference to FIGS. 29 to 31B. The inductor array 801 is different from the inductor array 401 including two internal conductors and two sets of external electrodes in that the inductor array 801 include four internal conductors and four sets of external electrodes. The following description does not mention the similarities between the inductor arrays 801 and 401.

The inductor array 801 includes internal conductors 425A, 425B, 425C and 425D disposed in the base body 10 and external electrodes 21A, 21B, 21C, 21D, 22A, 22B, 22C and 22D disposed on the surface of the base body 10. The internal conductors 425A and 425B are configured and arranged in the same manner as the internal conductors 425A and 425B included in the inductor array 401. The internal conductor 425C is connected at one end thereof to the external electrode 21C and connected at the other end thereof to the external electrode 22C. The internal conductor 425D is connected at one end thereof to the external electrode 21D and connected at the other end thereof to the external electrode 22D. As noted, the inductor array 801 includes a first inductor having the internal conductor 425A and external electrodes 21A and 22A, a second inductor having the internal conductor 425B and external electrodes 21B and 22B, a third inductor having the internal conductor 425C and external electrodes 21C and 22C, and a fourth inductor having the internal conductor 425D and external electrodes 21D and 22D. The eight external electrodes 21A to 21D and 22A to 22D of the inductor array 801 are arranged such that they can respectively face the corresponding lands 3 when the inductor array 801 is mounted on the mounting substrate 2a.

In the embodiment shown, the internal conductor 425C is positioned, in the L-axis direction, opposite the internal conductor 425A with the internal conductor 425B being positioned therebetween. The internal conductor 425D is positioned, in the L-axis direction, opposite the internal conductor 425B with the internal conductor 425C being positioned therebetween. The internal conductors 425A, 425B, 425C and 425D are arranged in the stated order in the L-axis direction from the positive side to the negative side. The internal conductor 425A faces, on one of the sides in the direction extending along a first coil axis Ax1 (the positive side in the L-axis direction), the second end surface 10d of the base body 10. This means that no internal conductors are arranged between the internal conductor 425A and the second end surface 10d. The internal conductor 425D faces, on one of the sides in the direction extending along a fourth coil axis Ax4 (the negative side in the L-axis direction), the first end surface 10c of the base body 10. This means that no internal conductors are arranged between the internal conductor 425D and the first end surface 10c. The internal conductors 425B and 425C are interposed between the internal conductors 425A and 425D. In one or more embodiments of the present invention, the internal conductors 425C and 425D are arranged such that a coil axis Ax3 extends through not only a core region 10C within the internal conductor 425C but also a core region 10D within the internal conductor 425D and a coil axis Ax4 extends through not only the core region 10D within the internal conductor 425D but also the core region 10C within the internal conductor 425C.

As described above, the internal conductor 425B is spaced away from the internal conductor 425A by a distance G1 in the direction extending along the coil axis Ax1. The internal conductor 425C is spaced away from the internal conductor 425B by a distance G2 in the direction extending along the coil axis Ax1. The internal conductor 425D is spaced away from the internal conductor 425C by a distance G3 in the direction extending along the coil axis Ax1. In one or more embodiments of the invention, the spacing G2 between the internal conductors 425B and 425C is greater than the spacing G1 between the internal conductors 425A and 425B. In one or more embodiments of the invention, the spacing G2 between the internal conductors 425B and 425C is greater than the spacing G3 between the internal conductors 425C and 425D. The spacings G1 and G3 may be equal to or different from each other. The spacing G2 between the internal conductors 425B and 425C may be 0.3 mm or less.

The internal conductor 425C includes a winding portion 426C, a lead-out conductor 427C1 and a lead-out conductor 427C2. The winding portion 426C extends in a circumferential direction around the coil axis Ax3 extending in a direction parallel to the mounting surface 10b of the base body 10. In other words, the winding portion 426C is wound around the coil axis Ax3. The winding portion 426C is connected at one of the ends thereof to the lead-out conductor 427C1 and at the other end thereof to the lead-out conductor 427C2. The lead-out conductor 427C1 extends along the first side surface 10e from the bottom end thereof to the top end thereof. The lead-out conductor 427C2 extends along the second side surface 10f from the bottom end thereof to the top end thereof. The lead-out conductor 427C1 is connected to the external electrode 21C, and the lead-out conductor 427C2 is connected to the external electrode 22C. The winding portion 426C includes a winding pattern 426C1 provided on a magnetic layer constituting a part of the base body 10, a winding pattern 426C2 provided on another magnetic layer constituting a part of the base body 10, and a via VC connecting together the winding patterns 426C1 and 426C2. The shape of the winding portion 426C when seen in the direction of the coil axis Ax3 may be the same as at least one of the shape of the winding portion 426A when seen in the direction of the coil axis Ax1 or the shape of the winding portion 426B when seen in the direction of the coil axis Ax2.

The internal conductor 425D includes a winding portion 426D, a lead-out conductor 427D1 and a lead-out conductor 427D2. The winding portion 426D extends in a circumferential direction around the coil axis Ax4 extending in a direction parallel to the mounting surface 10b of the base body 10. In other words, the winding portion 426D is wound around the coil axis Ax4. The winding portion 426D is connected at one of the ends thereof to the lead-out conductor 427D1 and at the other end thereof to the lead-out conductor 427D2. The lead-out conductor 427D1 extends along the first side surface 10e from the bottom end thereof to the top end thereof. The lead-out conductor 427D2 extends along the second side surface 10f from the bottom end thereof to the top end thereof. The lead-out conductor 427D1 is connected to the external electrode 21D, and the lead-out conductor 427D2 is connected to the external electrode 22D. The winding portion 426D includes a winding pattern 426D1 provided on a magnetic layer constituting a part of the base body 10, a winding pattern 426D2 provided on another magnetic layer constituting a part of the base body 10, and a via VD connecting together the winding patterns 426D1 and 426D2. The shape of the winding portion 426D when seen in the direction of the coil axis Ax4 may be the same as at least one of the shape of the winding portion 426A when seen in the direction of the coil axis Ax1, the shape of the winding portion 426B when seen in the direction of the coil axis Ax2 or the shape of the winding portion 426C when seen in the direction of the coil axis Ax3.

In one or more embodiments of the present invention, like the first aspect ratio, the ratio of the dimension of the section of the winding pattern 426C1 in the direction perpendicular to the coil axis Ax3 to the dimension of the same section in the direction parallel to the coil axis Ax3 (a third aspect ratio) is greater than one. In one or more embodiments of the present invention, like the first aspect ratio, the ratio of the dimension of the section of the winding pattern 426D1 in the direction perpendicular to the coil axis Ax4 to the dimension of the same section in the direction parallel to the coil axis Ax4 (a fourth aspect ratio) is greater than one. The description made regarding the first aspect ratio also applies to the third and fourth aspect ratios.

Like the winding portions 426A and 426B, the winding portion 426C has a smaller size in the L-axis direction than in the T-axis direction in one or more embodiments of the present invention. Similarly, in one or more embodiments of the present invention, the winding portion 426D has a smaller size in the L-axis direction than in the T-axis direction.

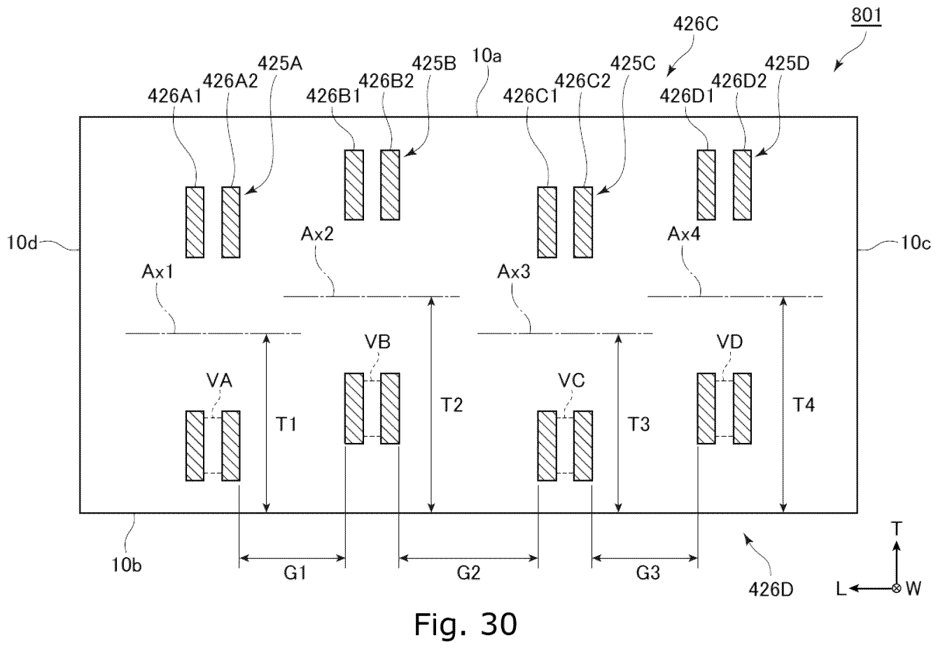

FIG. 30 is a sectional view schematically showing the section of the inductor array 801 along the VI-VI line. The section shown in FIG. 30 is obtained by cutting the inductor array 801 with a plane passing through the coil axis Ax1 and perpendicular to the second principal surface 10b. As shown in FIG. 30, in one or more embodiments of the present invention, the coil axes Ax3 and Ax4 extend parallel to the mounting surface 10b. The coil axes Ax3 and Ax4 may be orthogonal to at least one of the first end surface 10c or the second end surface 10d. In one or more embodiments of the present invention, the coil axis Ax3 is positioned away by a third distance T3 from the mounting surface 10b, and the coil axis Ax4 is positioned away by a fourth distance T4 greater than the third distance T3 from the mounting surface 10b. In other words, the fourth distance T4 between the coil axis Ax4 and the mounting surface 10b is greater than the third distance T3 between the coil axis Ax3 and the mounting surface 10b. In one or more embodiments of the present invention, the third distance T3 is equal to the first distance T1 between the mounting surface 10b and the coil axis Ax1. In one or more embodiments of the present invention, the fourth distance T4 is equal to the second distance T2 between the mounting surface 10b and the coil axis Ax2.

The inductor array 801 may include three inductors, or five or more inductors. When the inductor array 801 includes five or more inductors, the distance between the mounting surface 10b and the coil axis of the internal conductor of the n-th inductor (n is an odd number) from the outermost inductor on the positive side in the L-axis direction may be the same irrespective of the value of n. When the inductor array 801 includes five or more inductors, the distance between the mounting surface 10b and the coil axis of the internal conductor of the n-th inductor (n is an even number) from the outermost inductor on the positive side in the L-axis direction may be the same irrespective of the value of n.

Next, a description is given of an example method of manufacturing the inductor array 401 according to one embodiment of the present invention. To describe the manufacturing method, FIG. 17 will be referred to as necessary. In one or more embodiments of the present invention, the inductor array 401 is produced by the sheet lamination method, in which magnetic sheets are stacked together. The first step of the sheet lamination method for producing the inductor array 401 is to prepare the magnetic sheets. The magnetic sheets are, for example, made from a slurry obtained by mixing and kneading a resin and metal magnetic particles of a soft magnetic material. The slurry is molded into the magnetic sheets using a sheet molding machine such as a doctor blade sheet molding machine. The resin mixed and kneaded together with the metal magnetic particles may be, for example, a polyvinyl butyral (PVB) resin, an epoxy resin, or any other resin materials having an excellent insulation property.

The magnetic sheets are cut into a predetermined shape. The resulting magnetic sheets are penetrated in the thickness direction to form a through-hole at a predetermined position. Next, a conductive paste is applied to one of the magnetic sheets cut into a predetermined shape by a known method such as screen printing, thereby forming a plurality of unfired conductor patterns that will later form the winding pattern 426A1 and lead-out conductor 427A1 after firing. Likewise, the conductive paste is also applied to another one of the magnetic sheets, thereby forming a plurality of unfired conductor patterns that will later form the winding pattern 426A2 and lead-out conductor 427A2 after firing. The conductive paste is also applied to still another one of the magnetic sheets, thereby forming a plurality of unfired conductor patterns that will later form the winding pattern 426B1 and lead-out conductor 427B1 after firing, and the conductive paste is similarly applied to further another one of the magnetic sheets, thereby forming a plurality of unfired conductor patterns that will later form the winding pattern 426B2 and lead-out conductor 427B2 after firing. In forming the unfired conductor patterns, the conductive paste is poured into the through-hole in the magnetic sheets. The conductive paste poured into the through holed forms unfired vias, which will later form the vias VA and VB after firing. The conductive paste is made by mixing and kneading, for example, Ag, Cu, or alloys thereof and a resin.

In the way described above, the magnetic sheets having the unfired conductor patterns formed thereon and the unfired vias formed therein are prepared, and a mother laminate is prepared by stacking together these magnetic sheets and magnetic sheets having no conductors therein or thereon. In the mother laminate, adjacent ones of the unfired conductor patterns are connected together through the unfired vias, thereby forming unfired coil patterns, which are to form the internal conductors 425A and 425B once fired. The magnetic sheets having no conductors formed therein or thereon can contribute to adjust the distance between the internal conductors 425A and 425B.

Next, the mother laminate is diced using a cutter such as a dicing machine or a laser processing machine to obtain a chip laminate.

Next, the chip laminate is subjected to heat treatment at a temperature of 600° C. to 850° C. for a duration of 20 to 120 minutes. Through this heat treatment, the chip laminate is degreased and the magnetic sheets and conductive paste are fired, so that the base body 10 having the internal conductors 425A and 425B therein is prepared. When the magnetic sheets contain a thermosetting resin, the thermosetting resin may be cured by performing heat treatment on the chip laminate at a lower temperature. The cured resin can serve as a binder binding together the metal magnetic particles contained in the magnetic sheets. The low-temperature heat treatment is performed at a temperature within a range of 100° C. to 200° C. for a duration of approximately 20 to 120 minutes, for example.

Following the heat treatment, a conductive paste is applied to the surface of the heat-treated chip laminate (that is, the base body 10) to form the external electrodes 21A, 22A, 21B and 22B. In the above-described manner, the inductor array 401 is obtained. The inductor arrays 501, 601, 701 and 801 can be made using the same manufacturing method as the inductor array 401.

The above-described manufacturing method can be modified by omitting some of the steps, adding steps not explicitly described, and/or reordering the steps. Such omission, addition, or reordering is also included in the scope of the present invention unless diverged from the purport of the present invention.

The method of manufacturing the inductor array 401 is not limited to the method described above. The inductor array 401 may be produced by a lamination method other than the sheet lamination method (e.g., the printing lamination method), the thin film process, the compression molding process, or other known methods.

Next, advantageous effects of the foregoing embodiments will be described. In one or more embodiments of the present invention, the internal conductors 425A and 425B are arranged such that their coil axes Ax1 and Ax2 run parallel to the mounting surface 10b of the base body 10. With such arrangement, the inductor array 401, 501, 601, 701, 801 can be reduced in size in the direction extending along the mounting surface 10b.

In one or more embodiments of the present invention, the coil axis Ax2 is spaced away from the coil axis Ax1. Such arrangement can lessen the magnetic interference between the internal conductors 425A and 425B. The one or more embodiments of the present invention can thus lessen the magnetic coupling between the internal conductors 425A and 425B, when compared with inductor arrays having the internal conductors 425A and 425B arranged such that their coil axes Ax1 and Ax2 are coincident with each other. As has been described above, in one or more embodiments of the present invention, the base body 10 is configured with a relative magnetic permeability of 100 or less in order to achieve low inductance. When the base body 10 has a relative magnetic permeability of 100 or less, there are difficulties in keeping the magnetic flux generated by the internal conductor 425A in the vicinity of the internal conductor 425A and in keeping the magnetic flux generated by the internal conductor 425B in the vicinity of the internal conductor 425B. For this reason, reducing the distance G1 between the internal conductors 425A and 425B is likely to increase the magnetic coupling between the internal conductors 425A and 425B. In one or more embodiments of the present invention, the coil axis Ax2 is spaced away from the coil axis Ax1 as mentioned above. Such arrangement can lessen the magnetic coupling between the internal conductors 425A and 425B irrespective of a short distance G1 (for example, 0.3 mm or less) between the internal conductors 425A and 425B.

With the above-described design, one or more embodiments of the present invention can provide the inductor array 401, 501, 601, 701, 801, which can achieve size reduction in the direction extending along the mounting surface 10b and have lessened magnetic coupling between the inductors.

In one or more embodiments of the present invention, the base body 10 is configured to have a relative magnetic permeability of 100 or less, so that the inductor array 401, 501, 601, 701, 801 can achieve low inductance. In one or more embodiments of the present invention, the base body 10 may be configured such that its relative magnetic permeability is within the range of 30 to 100 throughout the entire region. If the base body 10 includes a region where the relative magnetic permeability is less than 30, the region may substantially serve as a magnetic gap. If the base body 10 includes a low-permeability region that may serve as a magnetic gap, the magnetic flux generated by one of the internal conductors 425A and 425B may avoid following a magnetic path extending through the low-permeability region and be thus likely to interfere with the other internal conductor. Furthermore, if the base body 10 includes a low-permeability region that may serve as a magnetic gap, this may result in magnetic flux leakage and increase magnetic interference with devices other than the inductor array 401, 501, 601, 701, 801. Having a relative magnetic permeability in a range of 30 to 100 throughout the entire region, the base body 10 includes no region serving as a magnetic gap. With such a design, magnetic coupling can be lessened between the internal conductors included in the inductor array 401, 501, 601, 701, 801, and magnetic interference can be prevented from affecting devices other than the inductor array 401, 501, 601, 701, 801.

In one or more embodiments of the present invention, the first aspect ratio or the ratio of the dimension a1 of the section of the winding portion 426A in the direction perpendicular to the coil axis Ax1 to the dimension a2 of the section of the winding portion 426A in the direction parallel to the coil axis Ax1 is greater than one. With such a design, the magnetic flux generated by the winding portion 426A including the winding pattern 426A1 is more likely to be directed in the direction perpendicular to the coil axis Ax1 than in the direction parallel to the coil axis Ax1. Accordingly, the magnetic flux generated by the winding portion 426A of the internal conductor 425A is less likely to reach the internal conductor 425B than magnetic flux generated by an inductor including a winding portion having a first aspect ratio of 1 or less. As a consequence, the magnetic coupling between the internal conductors 425A and 425B can be lessened.

In one or more embodiments of the invention, the second aspect ratio of the winding patterns 426B1 and 426B2 included in the winding portion 426B of the internal conductor 425B may be greater than one. This can further lessen the magnetic coupling between the internal conductors 425A and 425B.

In one or more embodiments of the invention, the third aspect ratio of the winding patterns 426C1 and 426C2 included in the winding portion 426C of the internal conductor 425C may be greater than one. This can reduce the magnetic coupling between the internal conductor 425C and other internal conductors (for example, the internal conductors 425B and 425D). In one or more embodiments of the invention, the fourth aspect ratio of the winding patterns 426D1 and 426D2 included in the winding portion 426D of the internal conductor 425D may be also greater than one. This can reduce the magnetic coupling between the internal conductor 425D and other internal conductors (for example, the internal conductor 425C).

In one or more embodiments of the present invention, the winding patterns 426A1 and 426A2 have a rounded section when cut along a plane passing through the coil axis Ax1. This design allows the magnetic flux generated by the winding patterns 426A1 and 426A2 of the internal conductor 425A to be likely to follow a path closer to the center of the section of the winding patterns 426A1 and 426A2. Accordingly, the magnetic flux generated by the winding patterns 426A1 and 426A2 of the internal conductor 425A is less likely to reach other internal conductors (for example, the internal conductor 425B). As a consequence, the magnetic coupling between the internal conductor 425A and other internal conductors can be lessened. In one or more embodiments of the present invention, the winding patterns constituting the internal conductors other than the internal conductor 425A may have a rounded section when cut along a plane passing through their own coil axes. This can reduce the magnetic coupling between the internal conductors.

In the inductor array 401 according to one or more embodiments of the present invention, the internal conductors 425B and 425C are arranged between the internal conductors 425A and 425D in the direction extending along the coil axis Ax2. With such a design, the magnetic flux generated by the internal conductor 425B and the magnetic flux generated by the internal conductor 425C are less likely to leak out of the base body 10 than the magnetic flux generated by the internal conductors 425A and 425D. On the other hand, since the internal conductor 425A faces, in the direction extending along the coil axis Ax1, the second end surface 10d of the base body 10, the magnetic flux generated by the internal conductor 425A is likely to leak out of the base body 10. Similarly, since the internal conductor 425D faces, in the direction extending along the coil axis Ax4, the first end surface 10c of the base body 10, the magnetic flux generated by the internal conductor 425D is likely to leak out of the base body 10. The above arrangement is likely to result in the magnetic coupling between the internal conductors 425B and 425C being stronger than the magnetic coupling between the internal conductors 425A and 425B and the magnetic coupling between the internal conductors 425C and 425D. According to one or more embodiments of the present invention, the spacing G2 between the internal conductors 425B and 425C is greater than the spacing G1 between the internal conductors 425A and 425B. This lessens the magnetic coupling between the internal conductors 425B and 425C, thereby reducing the strength of the magnetic coupling between the internal conductors 425B and 425C to reach a similar level as the strength of the magnetic coupling between the internal conductors 425A and 425B. Likewise, the spacing G2 between the internal conductors 425B and 425C is greater than the spacing G3 between the internal conductors 425C and 425D. This lessens the magnetic coupling between the internal conductors 425B and 425C, thereby reducing the strength of the magnetic coupling between the internal conductors 425B and 425C to reach a similar level as the strength of the magnetic coupling between the internal conductors 425C and 425D.

The dimensions, materials, and arrangements of the constituent elements described herein are not limited to those explicitly described for the embodiments, and these constituent elements can be modified to have any dimensions, materials, and arrangements within the scope of the present invention. Furthermore, constituent elements not explicitly described herein can also be added to the described embodiments, and it is also possible to omit some of the constituent elements described for the embodiments.

The words “first,” “second,” and “third” used herein are added to distinguish constituent elements but do not necessarily limit the number, order, or detailed specifics of the constituent elements. The reference numbers added to distinguish the constituent elements should be construed in each context. The same reference numbers do not necessarily denote the same constituent elements in more than one context. Although identified by particular reference numbers, constituent elements are not prevented from performing functions of constituent elements identified by other reference numbers.

What is claimed is:

1. An inductor array comprising:
a base body containing a plurality of metal magnetic particles, the base body having a first surface;
a first coil conductor provided in the base body, the first coil conductor including a first winding portion wound around a first coil axis that extends in a direction parallel to the first surface and that is positioned away by a first distance from the first surface;
a second coil conductor provided in the base body, the second coil conductor including a second winding portion wound around a second coil axis that extends in a direction parallel to the first coil axis and that is positioned away by a second distance greater than the first distance from the first surface;
a first external electrode provided on the base body such that the first external electrode is in contact at least with the first surface, the first external electrode being connected to one end of the first coil conductor;
a second external electrode provided on the base body such that the second external electrode is in contact at least with the first surface, the second external electrode being connected to another end of the first coil conductor;
a third external electrode provided on the base body such that the third external electrode is in contact at least with the first surface, the third external electrode being connected to one end of the second coil conductor; and
a fourth external electrode provided on the base body such that the fourth external electrode is in contact at least with the first surface, the fourth external electrode being connected to another end of the second coil conductor.

2. The inductor array of claim 1, wherein a distance between the first coil conductor and the second coil conductor in a direction along the first coil axis is 0.3 mm or less.

3. The inductor array of claim 1, wherein the base body has a relative magnetic permeability of 100 or less.

4. The inductor array of claim 1,
wherein the first winding portion is wound around the first coil axis 1.5 turns or less, and
wherein the second winding portion is wound around the second coil axis 1.5 turns or less.

5. The inductor array of claim 1, wherein a shape of the first winding portion as viewed in a direction of the first coil axis is the same as a shape of the second winding portion as viewed in a direction of the second coil axis.

6. The inductor array of claim 1, wherein an absolute value of a coefficient of coupling between the first and second coil conductors is 0.15 or less.

7. The inductor array of claim 1, wherein a section of the first winding portion has a first aspect ratio of greater than one, where the first aspect ratio denotes a ratio of (i) a dimension of the section in a direction perpendicular to the first coil axis to (ii) a dimension of the section in a direction parallel to the first coil axis.

8. The inductor array of claim 1, wherein a section of the second winding portion has a second aspect ratio of greater than one, where the second aspect ratio denotes a ratio of (i) a dimension of the section in a direction perpendicular to the second coil axis to (ii) a dimension of the section in a direction parallel to the second coil axis.

9. The inductor array of claim 1,
wherein the first winding portion has a first winding pattern extending around the first coil axis, and
wherein the first winding pattern has a rounded section when cut along a plane passing through the first coil axis.

10. The inductor array of claim 1,
wherein the base body has a first end surface connected to the first surface, wherein the first coil conductor includes a first lead-out conductor that is connected to one end of the first winding portion and that extends along the first end surface, and
wherein the first external electrode is connected to the first coil conductor via the first lead-out conductor.

11. The inductor array of claim 1, further comprising:
a third coil conductor provided in the base body such that the third coil conductor is positioned opposite the first coil conductor with respect to the second coil conductor, the third coil conductor having a third winding portion wound around a third coil axis extending in a direction parallel to the first coil axis, the third coil axis being spaced away by a third distance less than the second distance from the first surface;
a fifth external electrode connected to one end of the third coil conductor; and
a sixth external electrode connected to another end of the third coil conductor.

12. The inductor array of claim 11, wherein the third distance is equal to the first distance.

13. The inductor array of claim 11, a shape of the third winding portion as viewed in a direction of the third coil axis is the same as at least one of a shape of the first winding portion as viewed in a direction of the first coil axis or a shape of the second winding portion as viewed in a direction of the second coil axis.

14. The inductor array of claim 11,
wherein the base body has a first end surface connected to the first surface, wherein the first coil conductor faces, in the direction along the first coil axis, the first end surface of the base body, and
wherein a distance between the second coil conductor and the third coil conductor in a direction along the first coil axis is greater than a distance between the first coil conductor and the second coil conductor in the direction along the first coil axis.

15. The inductor array of claim 11, further comprising:
a fourth coil conductor provided in the base body such that the fourth coil conductor is positioned opposite the second coil conductor with respect to the third coil conductor, the fourth coil conductor having a fourth winding portion wound around a fourth coil axis extending in a direction parallel to the first coil axis, the fourth coil axis being spaced away by a fourth distance greater than the third distance from the first surface;
a seventh external electrode connected to one end of the fourth coil conductor; and
an eighth external electrode connected to another end of the fourth coil conductor.

16. The inductor array of claim 15, wherein the fourth distance is equal to the second distance.

17. The inductor array of claim 15, a shape of the fourth winding portion as viewed in a direction of the fourth coil axis is the same as at least one of a shape of the first winding portion as viewed in a direction of the first coil axis, a shape of the second winding portion as viewed in a direction of the second coil axis, or a shape of the third winding portion as viewed in a direction of the third coil axis.

18. The inductor array of claim 15,
wherein the base body has a second end surface that is connected to the first surface and opposed to the first end surface,
wherein the fourth coil conductor faces, in the direction along the first coil axis, the second end surface of the base body, and
wherein a distance between the second coil conductor and the third coil conductor in a direction along the third coil axis is greater than a distance between the third coil conductor and the fourth coil conductor in the direction along the third coil axis.

19. A circuit board comprising the inductor array of claim 1.

20. An electronic device comprising the circuit board of claim 19.
